(19) United States
(12) Patent Application Publication
(10) Pub. No.: US 2024/0324320 A1
(43) Pub. Date: Sep. 26, 2024

(54) DISPLAY DEVICE AND METHOD FOR FABRICATING THE SAME

(71) Applicant: Samsung Display Co., LTD., Yongin-si (KR)

(72) Inventors: Ki Won KIM, Yongin-si (KR); Jeong Ju PARK, Yongin-si (KR); Seung Sok SON, Yongin-si (KR); Kap Soo YOON, Yongin-si (KR); Woo Geun LEE, Yongin-si (KR); Ji Yun HONG, Yongin-si (KR)

(73) Assignee: Samsung Display Co., LTD., Yongin-si (KR)

(21) Appl. No.: 18/517,068

(22) Filed: Nov. 22, 2023

(30) Foreign Application Priority Data
Mar. 20, 2023 (KR) 10-2023-0035846

(51) Int. Cl. H10K 59/123; H10K 59/12; H10K 71/60

(52) U.S. Cl. CPC H10K 59/123; H10K 59/1201; H10K 71/60

(57) ABSTRACT

A method for fabricating a display device includes providing a substrate into a chamber; forming an active material layer on the substrate by a plurality of deposition processes in the chamber; forming an active layer by patterning the active material layer: forming a transistor including a gate electrode overlapping the active layer; and forming a pixel electrode on the transistor, at least two deposition processes among the plurality of deposition processes are performed by applying different magnitudes of power, respectively.

### CROSS-REFERENCE TO RELATED APPLICATION(S)

This application claims priority to and benefits of Korean Patent Application No. 10-2023-0035846 under 35 U.S.C. § 119, filed on Mar. 20, 2023, in the Korean Intellectual Property Office, the entire contents of which are incorporated herein by reference.

### BACKGROUND

### 1. Technical Field

Embodiments relate to a display device and a method for fabricating the display device.

### 2. Description of the Related Art

An organic light emitting display device includes a display element such as an organic light emitting diode whose luminance is changed by current.

### SUMMARY

Embodiments provide a display device capable of improving element reliability and a method for fabricating the display device.

However, embodiments are not limited to those set forth herein. The above and other embodiments will become more apparent to one of ordinary skill in the art to which the disclosure pertains by referencing the detailed description of the disclosure given below.

According to an embodiment, a method for fabricating a display device may include: providing a substrate into a chamber; forming an active material layer on the substrate by a plurality of deposition processes in the chamber; forming an active layer by patterning the active material layer: forming a transistor including a gate electrode overlapping the active layer; and forming a pixel electrode on the transistor, wherein at least two deposition processes among the plurality of deposition processes may be performed by applying different magnitudes of power, respectively.

In an embodiment, the at least two deposition processes may be performed by applying different flow rates of oxygen gas, respectively.

In an embodiment, the active layer may include: a first sub-active layer disposed in a first sub-active area adjacent to the substrate; a second sub-active layer disposed in a second sub-active area on the first sub-active area; and a third sub-active layer disposed in a third sub-active area on the second sub-active area.

In an embodiment, the first sub-active layer, the second sub-active layer, and the third sub-active layer may be integral with each other without an interface.

In an embodiment, a first interface may be formed between the first sub-active layer and the second sub-active layer, and a second interface may be formed between the second sub-active layer and the third sub-active layer.

In an embodiment, the method may further include: forming a buffer film between the substrate and the active layer; and forming a gate insulating film between the gate electrode and the active layer, wherein the first sub-active area may be disposed adjacent to the buffer film, the third sub-active area may be disposed adjacent to the gate insulating film, and the second sub-active area may be disposed between the first sub-active area and the third sub-active area.

In an embodiment, the first sub-active layer in the first sub-active area may be in contact with the buffer film, and the third sub-active layer in the third sub-active area may be in contact with the gate insulating film.

In an embodiment, the chamber may include: a first deposition area for depositing a first sub-active material layer in the first sub-active area on the substrate; a second deposition area for depositing a second sub-active material layer in the second sub-active area on the substrate; and a third deposition area for depositing a third sub-active material layer in the third sub-active area on the substrate.

In an embodiment, the method may further include: providing the substrate to the first deposition area; providing the substrate to the second deposition area; and providing the substrate to the third deposition area.

In an embodiment, the plurality of deposition processes may include: forming the first sub-active material layer in the first sub-active area on the substrate by applying a first power to the first deposition area; forming the second sub-active material layer in the second sub-active area on the substrate in an atmosphere in which a second power is provided to the second deposition area; and forming the third sub-active material layer in the third sub-active area on the substrate by applying a third power to the third deposition area, and at least two of the first, second, and third powers may have different magnitudes.

In an embodiment, the first power may have a magnitude different from a magnitude of the second power, and the third power may have a magnitude different from the magnitude of the second power.

In an embodiment, the first sub-active material layer, the second sub-active material layer, and the third sub-active material layer may be integral with each other without an interface.

In an embodiment, a first interface may be formed between the first sub-active material layer and the second sub-active material layer, and a second interface may be formed between the second sub-active material layer and the third sub-active material layer.

In an embodiment, the forming of the first sub-active material layer may be performed by applying oxygen gas of a first flow rate to the first deposition area, the forming of the second sub-active material layer may be performed by applying oxygen gas of a second flow rate to the second deposition area, the forming of the third sub-active material layer may be performed by applying oxygen gas of a third flow rate to the third deposition area, and at least two of the first to third flow rates may have different magnitudes.

In an embodiment, the second flow rate may be greater than the first flow rate and/or the third flow rate, and the second power may be smaller than the first power and/or the third power.

According to an embodiment, a display device may include: a substrate; an active layer on the substrate; a transistor including a gate electrode overlapping the active layer; and a pixel electrode on the transistor, wherein the active layer may include a first sub-active layer adjacent to the substrate, a second sub-active layer disposed on the first sub-active layer, and a third sub-active layer disposed on the second sub-active layer, the second sub-active layer may be disposed between the first sub-active layer and the third sub-active layer, and the second sub-active layer may have an amount of oxygen vacancies smaller than those of the first sub-active layer and/or the third sub-active layer.

In an embodiment, the second sub-active layer may include an amount of hydrogen larger than those of the first sub-active layer and/or the third sub-active layer.

In an embodiment, the second sub-active layer may include an amount of oxygen-metal bonding components larger than those of the first sub-active layer and/or the third sub-active layer.

In an embodiment, the second sub-active layer may include an amount of metal-OH bonding components smaller than those of the first sub-active layer and/or the third sub-active layer.

In an embodiment, the at least two of the first, second, and third sub-active layers may have different densities.

In an embodiment, the first sub-active layer, the second sub-active layer, and the third sub-active layer may be integral with each other without an interface.

In an embodiment, a first interface may be formed between the first sub-active layer and the second sub-active layer, and a second interface may be formed between the second sub-active layer and the third sub-active layer.

According to the disclosure, in case that a plurality of sub-active material layers are deposited in the same chamber, since the magnitude of power and a flow rate of oxygen gas in each deposition area may be individually controlled for each deposition area, appropriate power may be applied according to characteristics of a driving transistor for each deposition process, and oxygen gas may be supplied at an appropriate flow rate. Therefore, a driving transistor (or switching transistor) fabricated according to the fabricating method of the disclosure may have an optimal threshold voltage capable of maintaining reliability.

It should be noted that the effects of the disclosure are not limited to those described above, and other effects not mentioned will be clearly understood by those skilled in the art from the description below.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view illustrating a display device according to an embodiment;

FIG. 3 is a schematic plan view illustrating a display unit of the display device according to an embodiment;

FIG. 4 is a schematic block diagram illustrating a display panel and a display driver according to an embodiment;

FIG. 5 is a schematic diagram of an equivalent circuit of a pixel of the display device according to an embodiment;

FIG. 6 is a schematic cross-sectional view of the display device according to an embodiment;

FIG. 7 is an enlarged schematic view of portion A of FIG. 6;

FIG. 8 is a schematic view of a sputtering device according to an embodiment;

FIG. 9 is a schematic diagram of a target portion according to an embodiment;

FIG. 10 is a schematic diagram for explaining a change in threshold voltage of a driving transistor according to a flow rate of oxygen gas introduced (or supplied) during a deposition process;

FIG. 11 is a schematic diagram for explaining a change in threshold voltage of a switching transistor according to a flow rate of oxygen gas introduced (or supplied) during a deposition process;

FIG. 12 is a schematic diagram for explaining a change amount (or variation) of a threshold voltage of a driving transistor according to a flow rate of oxygen gas introduced (or supplied) during a deposition process;

FIG. 13 is a schematic diagram for explaining a change amount (or variation) of a stress threshold voltage of a switching transistor according to a flow rate of oxygen gas introduced (or supplied) during a deposition process;

FIG. 14 is a schematic diagram for explaining a change in threshold voltage of a driving transistor according to a power introduced (or supplied) during a deposition process;

FIG. 15 is a schematic diagram for explaining a change in threshold voltage of a switching transistor according to a power introduced (or supplied) during a deposition process;

FIG. 16 is a schematic diagram for explaining a change amount (or variation) of a threshold voltage of a driving transistor according to a power introduced during a deposition process;

FIG. 17 is a schematic diagram for explaining a change amount (or variation) of a stress threshold voltage of a driving transistor according to a power introduced (or supplied) during a deposition process;

FIG. 18 is a schematic diagram for explaining a ratio occupied by oxygen vacancy among components of an active layer ACT of a display device according to an embodiment;

FIG. 19 is a schematic diagram for explaining ratios of metal-oxygen components among components of an active layer of a display device according to an embodiment;

FIG. 20 is a schematic diagram for explaining ratios of metal and hydroxide (OH—) components among components of an active layer of a display device according to an embodiment;

FIG. 21 is a schematic diagram for explaining intensities of main components of an active layer of a display device according to an embodiment;

FIG. 22 is a schematic cross-sectional view illustrating a display element according to an embodiment;

FIGS. 23, 24, 25, and 26 are schematic cross-sectional views illustrating a structure of a light emitting element according to an embodiment;

FIG. 27 is a schematic cross-sectional view illustrating an example of an organic light emitting diode of FIG. 25;

FIG. 28 is a schematic cross-sectional view illustrating an example of an organic light emitting diode of FIG. 26; and

FIG. 29 is a schematic cross-sectional view illustrating a structure of a pixel of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only. Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which are formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, specific embodiments will be described with reference to the accompanying drawings.

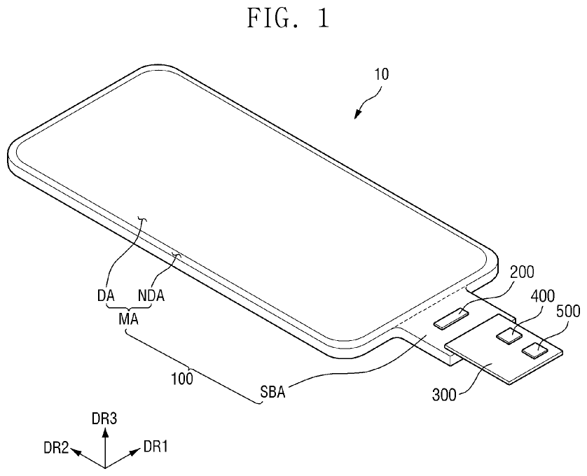

FIG. 1 is a schematic perspective view illustrating a display device according to an embodiment.

Referring to FIG. 1, a display device 10 may be applied to portable electronic devices such as a mobile phone, a smartphone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IoT). As another example, the display device 10 may be applied to a wearable device such as a smart watch, a watch phone, a glasses-type display, and a head mounted display (HMD).

The display device 10 may be formed in a planar shape similar to a quadrangle. For example, the display device 10 may have a planar shape similar to a quadrangle having a short side in a first direction DR1 and a long side in a second direction DR2. A corner where the short side in the first direction DR1 and the long side in the second direction DR2 meet may be rounded to have a predetermined curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels displaying an image, and a non-display area NDA disposed around the display area DA. The display area DA may emit light from light emitting areas or opening areas. For example, the display panel 100 may include a pixel circuit including switching elements, a pixel defining film defining the light emitting areas or the opening areas, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but embodiments are not limited thereto.

The non-display area NDA may be an area outside the display area DA. The non-display area NDA may be defined as an edge area of the main area MA of the display panel 100. The non-display area NDA may include a gate driver supplying gate signals to gate lines, and fan-out lines connecting the display driver 200 and the display area DA.

The sub-area SBA may extend from a side of the main area MA. The sub-area SBA may include a flexible material that is bendable, foldable, rollable, or the like. For example, in case that the sub-area SBA is bent, the sub-area SBA may overlap the main area MA in a thickness direction (e.g., a third direction DR3). The sub-area SBA may include a pad portion connected to the display driver 200 and the circuit board 300. In another example, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction (e.g., the third direction DR3) by bending of the sub-area SBA. As another example, the display driver 200 may be mounted on the circuit board 300.

The circuit board 300 may be attached onto the pad portion of the display panel 100 by an anisotropic conductive film (ACF). Lead lines of the circuit board 300 may be electrically connected to the pad portion of the display panel 100. The circuit board 300 may be a flexible film such as a flexible printed circuit board, a printed circuit board, or a chip on film.

The touch driver 400 may be mounted on the circuit board 300. The touch driver 400 may be electrically connected to a touch sensing unit of the display panel 100. The touch driver 400 may supply a touch driving signal to touch electrodes of the touch sensing unit, and may sense an amount of change in capacitance between the touch electrodes. For example, the touch driving signal may be a pulse signal having a predetermined frequency. The touch driver 400 may calculate whether an input is made and input coordinates based on the amount of change in capacitance between the touch electrodes. The touch driver 400 may be formed as an integrated circuit (IC).

The power supply unit 500 may be disposed on the circuit board 300, and may supply a power voltage to the display driver 200 and the display panel 100. The power supply unit 500 may generate a first driving voltage to supply the first driving voltage to a first driving voltage line VDL, generate initialization voltages (e.g., a first initialization voltage and a second initialization voltage) to supply the initialization voltages to initialization voltage lines VIL (e.g., a first initialization voltage line and a second initialization voltage line), and generate a common voltage to supply the common voltage to a common electrode, which is common to light emitting elements of pixels. For example, the first driving voltage may be a high potential voltage for driving the light emitting element, and the common voltage may be a low potential voltage for driving the light emitting element.

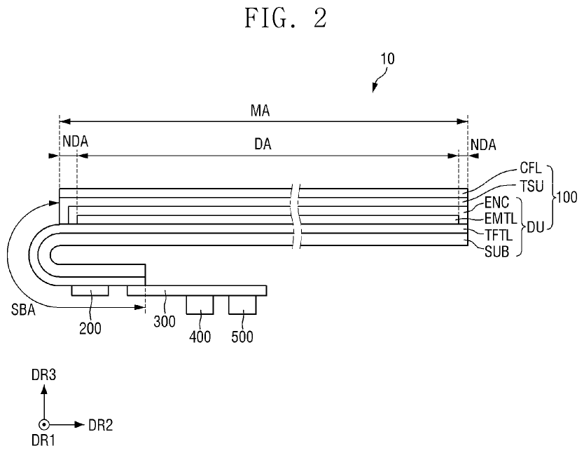

FIG. 2 is a schematic cross-sectional view illustrating a display device according to an embodiment.

Referring to FIG. 2, the display panel 100 may include a display unit DU, a touch sensing unit TSU, and a color filter layer CFL. The display unit DU may include a substrate SUB, a thin film transistor layer TFTL, a light emitting element layer EMTL, and an encapsulation layer ENC.

The substrate SUB may be a base substrate SUB or a base member. The substrate SUB may be a flexible substrate SUB that is bendable, foldable, rollable, or the like. For example, the substrate SUB may include a polymer resin such as polyimide PI, but embodiments are not limited thereto. As another example, the substrate SUB may include a glass material or a metal material.

The thin film transistor layer TFTL may be disposed on the substrate SUB. The thin film transistor layer TFTL may include thin film transistors of a pixel circuit of pixels. The thin film transistor layer TFTL may further include gate lines, data lines, power lines, gate control lines, fan-out lines connecting the display driver 200 and the data lines, and lead lines connecting the display driver 200 and the pad portion. Each of the thin film transistors may include a semiconductor area, a source electrode, a drain electrode, and a gate electrode. For example, in case that the gate driver is formed on a side of the non-display area NDA of the display panel 100, the gate driver may include the thin film transistors.

The thin film transistor layer TFTL may be disposed in the display area DA, the non-display area NDA, and the sub-area SBA. The thin film transistors, the gate lines, the data lines, and the power lines of each of the pixels of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EMTL may be disposed on the thin film transistor layer TFTL. The light emitting element layer EMTL may include light emitting elements in which a pixel electrode, a light emitting layer, and a common electrode are sequentially stacked to emit light, and a pixel defining film, which defines pixels. The light emitting elements of the light emitting element layer EMTL may be disposed in the display area DA.

For example, the light emitting layer may be an organic light emitting layer including an organic material. The light emitting layer may include a hole transporting layer, an organic light emitting layer, and an electron transporting layer. In case that the pixel electrode receives a predetermined voltage through the thin film transistor of the thin film transistor layer TFTL, and the common electrode receives a cathode voltage, holes and electrons may move to the organic light emitting layer through the hole transporting layer and the electron transporting layer, respectively, and may be bonded to each other in the organic light emitting layer to emit light. For example, the pixel electrode may be an anode electrode and the common electrode may be a cathode electrode, but embodiments are not limited thereto.

As another example, the light emitting elements may include a quantum dot light emitting diode including a quantum dot light emitting layer, an inorganic light emitting diode including an inorganic semiconductor, or a micro light emitting diode.

The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL.

The touch sensing unit TSU may be disposed on the encapsulation layer ENC. The touch sensing unit TSU may include touch electrodes for sensing a user's touch by a capacitance method, and touch lines connecting the touch electrodes and the touch driver 400. For example, the touch sensing unit TSU may sense the user's touch by a mutual capacitance method or a self-capacitance method.

As another example, the touch sensing unit TSU may be disposed on a separate substrate SUB disposed on the display unit DU. For example, the substrate SUB supporting the touch sensing unit TSU may be a base member that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include color filters corresponding to each of the light emitting areas. Each of the color filters may selectively transmit light of a specific wavelength and block or absorb light of a different wavelength. The color filter layer CFL may absorb a portion of light introduced (or supplied) from the outside of the display device 10 to reduce reflected light caused by external light. Therefore, the color filter layer CFL may prevent color distortion caused by reflection of external light.

As the color filter layer CFL is directly disposed on the touch sensing unit TSU, the display device 10 may not require a separate substrate SUB for the color filter layer CFL. Therefore, a thickness of the display device 10 may be relatively reduced.

The sub-area SBA of the display panel 100 may extend from a side of the main area MA. The sub-area SBA may include a flexible material that is bendable, foldable, rollable, or the like. For example, in case that the sub-area SBA is bent, the sub-area SBA may overlap the main area MA in the thickness direction (e.g., the third direction DR3). The sub-area SBA may include a pad portion electrically connected to the display driver 200 and the circuit board 300.

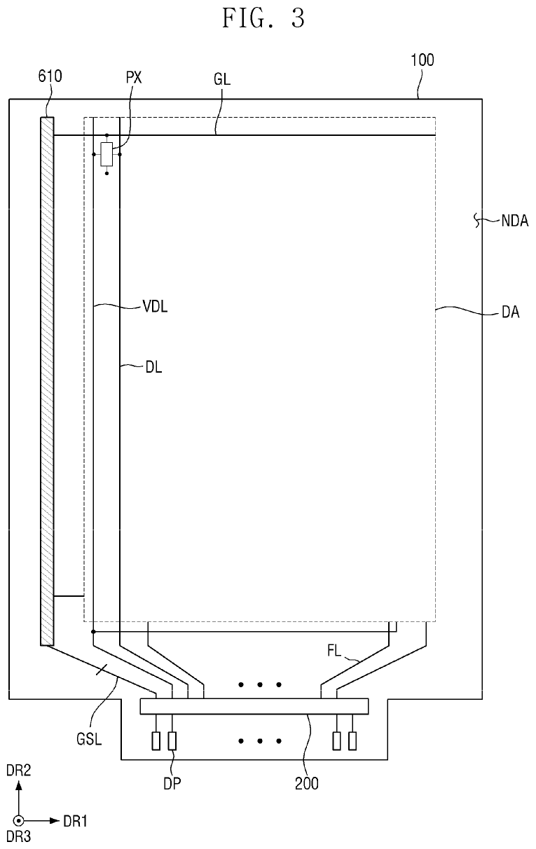

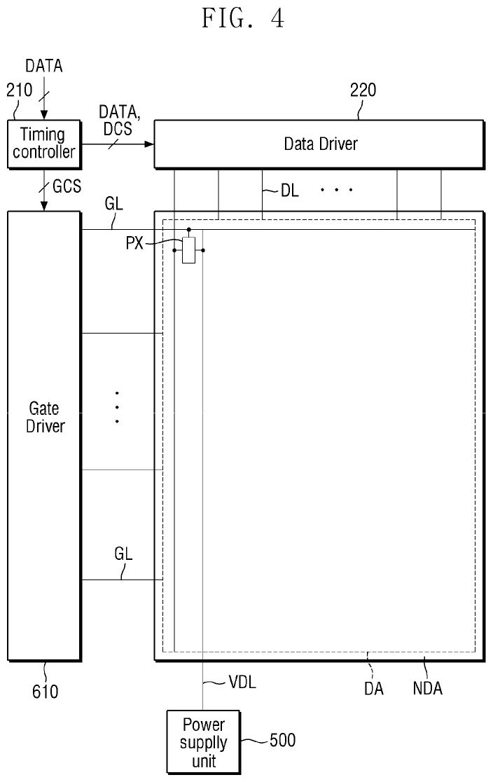

FIG. 3 is a schematic plan view illustrating a display unit of a display device according to an embodiment, and FIG. 4 is a schematic block diagram illustrating a display panel and a display driver according to an embodiment.

Referring to FIGS. 3 and 4, the display panel 100 may include a display area DA and a non-display area NDA.

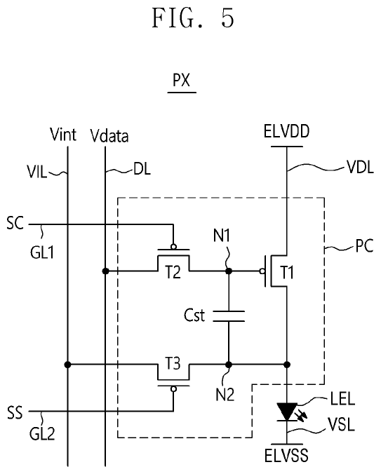

The display area DA may include pixels PX, driving voltage lines VDL connected to the pixels PX, gate lines GL of common voltage lines (e.g., VSL in FIG. 5), and data lines DL.

Each of the pixels PX may be connected to the gate line GL, the data line DL, the driving voltage line VDL, and the common voltage line VSL. Each of the pixels PX may include at least one transistor, a light emitting element, and a capacitor.

The gate lines GL may extend in the first direction DR1 and may be spaced apart from each other in the second direction DR2 intersecting the first direction DR1. The gate lines GL may be arranged along the second direction DR2. The gate lines GL may sequentially supply gate signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. The data voltage may determine luminance of each of the pixels PX.

The driving voltage lines VDL may extend in the second direction DR2 and may be spaced apart from each other in the first direction DR1. The driving voltage lines VDL may be arranged along the first direction DR1. The driving voltage lines VDL may supply driving voltages to the pixels PX. The driving voltage may be a high potential voltage for driving light emitting elements of the pixels PX.

The non-display area NDA may surround the display area DA. The non-display area NDA may include a gate driver 610, fan-out lines FL, and a gate control line GSL.

The fan-out lines FL may extend from the display driver 200 to the display area DA. The fan-out lines FL may supply the data voltages received from the display driver 200 to the data lines DL.

The gate control line GSL may extend from the display driver 200 to the gate driver 610. The gate control line GSL may supply the gate control signal GCS received from the display driver 200 to the gate driver 610.

The sub-area SBA may extend from a side of the non-display area NDA. The sub-area SBA may include the display driver 200 and the pad portion DP. The pad portion DP may be disposed closer to an edge portion of a side of the sub-area SBA than the display driver 200. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals input from the circuit board 300. Based on the timing signals, the timing controller 210 may control an operation timing of the data driver 220 by generating a data control signal DCS, and may control an operation timing of the gate driver 610 by generating a gate control signal GCS. In another example, the timing controller 210 may control an operation timing of a light emitting control driver by generating a light emitting control signal. The timing controller 210 may supply the gate control signal GCS to the gate driver 610 through the gate control line GSL. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. The gate signals of the gate driver 610 may select the pixels PX to which the data voltage is supplied, and the selected pixels PX may receive the data voltage through the data lines DL.

The power supply unit 500 may be disposed on the circuit board 300, and may supply a power voltage to the display driver 200 and the display panel 100. The power supply unit 500 may generate a first driving voltage to supply the first driving voltage to the driving voltage line VDL, generate an initialization voltage to supply the initialization voltage to an initialization voltage line, and generate a common voltage to supply the common voltage to the common electrode, which is common to the light emitting elements of the pixels. Such a common voltage may be applied to the common electrode through the common voltage line VSL.

The gate driver 610 may be disposed outside of a side of the display area DA or on a side of the non-display area NDA. For example, the light emitting control driver may be disposed outside of the other side of the display area DA or on another side of the non-display area NDA, but embodiments are not limited thereto. As another example, the gate driver 610 and the light emitting control driver 620 may be disposed on either a side or another side of the non-display area NDA.

The gate driver 610 may include transistors that generate gate signals based on the gate control signal GCS. The transistors of the gate driver 610 and the transistors of each of the pixels PX may be formed on the same layer. The gate driver 610 may supply the gate signals to the gate lines GL.

FIG. 5 is a schematic diagram of an equivalent circuit of a pixel of the display device according to an embodiment.

Referring to FIG. 5, the pixel PX may be connected to a first gate line GL1, a second gate line GL2, a data line DL, and an initialization voltage line VIL.

The pixel PX may include a pixel circuit PC and a light emitting element LEL.

The pixel circuit PC may include a first transistor T1, a second transistor T2, a third transistor T3, and a capacitor Cst.

The first transistor T1 may include a gate electrode, a source electrode, and a drain electrode. The first transistor T1 may control a drain-source current (hereinafter, referred to as a driving current) according to a data voltage applied to the gate electrode thereof. A driving current (e.g., Isd) flowing through a channel region of the first transistor T1 may be proportional to a square of a difference between a voltage Vsg between the source electrode and the gate electrode of the first transistor T1 and a threshold voltage Vth (e.g., Isd=k×(Vsg−Vth)²). Here, k is a proportional coefficient determined by a structure and physical characteristics of the first transistor T1, Vsg is a source-gate voltage of the first transistor T1, and Vth is a threshold voltage of the first transistor T1. The gate electrode of the first transistor T1 may be electrically connected to a first node N1, the drain electrode of the first transistor T1 may be electrically connected to the driving voltage line VDL, and the source electrode of the first transistor T1 may be electrically connected to a second node N2. The driving voltage line VDL may transmit a driving voltage ELVDD.

The light emitting element LEL may emit light by receiving the driving current Isd. The amount of light emitted from or luminance of the light emitting element LEL may be proportional to the magnitude of the driving current Isd. The light emitting element LEL may be an organic light emitting diode including a first electrode, a second electrode, and an organic light emitting layer disposed between the first electrode and the second electrode. As another example, the light emitting element LEL may be an inorganic light emitting element including a first electrode, a second electrode, and an inorganic semiconductor disposed between the first electrode and the second electrode. As still another example, the light emitting element LEL may be a quantum dot light emitting element including a first electrode, a second electrode, and a quantum dot light emitting layer disposed between the first electrode and the second electrode. As still another example, the light emitting element LEL may be a micro light emitting diode. The first electrode of the light emitting element LEL may be electrically connected to the second node N2. The first electrode of the light emitting element LEL may be connected to the source electrode of the first transistor T1, a drain electrode of the third transistor T3, and a second electrode of the capacitor Cst through the first node N1. The second electrode of the light emitting element LEL may be connected to the common voltage line VSL. The second electrode of the light emitting element LEL may receive a common voltage ELVSS (e.g., a low potential voltage) from the common voltage line VSL.

The second transistor T2 may be turned on by the first gate signal SC of the first gate line GL1 to electrically connect the data line DL and the first node N1, which is the gate electrode of the first transistor T1. The second transistor T2 may be turned on according to the first gate signal SC to supply a data voltage Vdata of the data line DL to the first node N1. A gate electrode of the second transistor T2 may be electrically connected to the first gate line GL1, a drain electrode of the second transistor T2 may be electrically connected to the data line DL, and a source electrode of the second transistor T2 may be electrically connected to the first node N1.

The third transistor T3 may be turned on by a second gate signal SS of the second gate line GL2 to electrically connect the initialization voltage line VIL and the second node N2, which is the first electrode of the light emitting element LEL. The third transistor T3 may be turned on based on the second gate signal SS to supply an initialization voltage Vint of the initialization voltage line VIL to the second node N2. The initialization voltage Vint may have a value smaller than a threshold voltage of the light emitting element LEL. A gate electrode of the third transistor T3 may be electrically connected to the second gate line GL2, a source electrode of the third transistor T3 may be electrically connected to the initialization voltage line VIL, and a drain electrode of the third transistor T3 may be electrically connected to the second node N2.

The capacitor Cst may be electrically connected between the first node N1, which is the gate electrode of the first transistor T1, and the second node N2, which is the source electrode of the first transistor T1. A first electrode of the capacitor Cst may be electrically connected to the first node N1, and a second electrode of the capacitor Cst may be electrically connected to the second node N2. The capacitor Cst may store, for example, the data voltage Vdata supplied from the data line DL through the first transistor T1.

The first transistor T1, the second transistor T2, and the third transistor T3 may include an oxide-based active layer. The oxide-based active layer may include, for example, indium-gallium-zinc-oxide (IGZO) or indium-gallium-zinc-tin oxide (IGZTO). The transistor including the oxide-based active layer may have a coplanar structure in which a gate electrode is disposed thereon. The transistor including the oxide-based active layer may correspond to an n-type transistor, and may output a current flowing into a drain electrode to a source electrode based on a gate high voltage applied to a gate electrode.

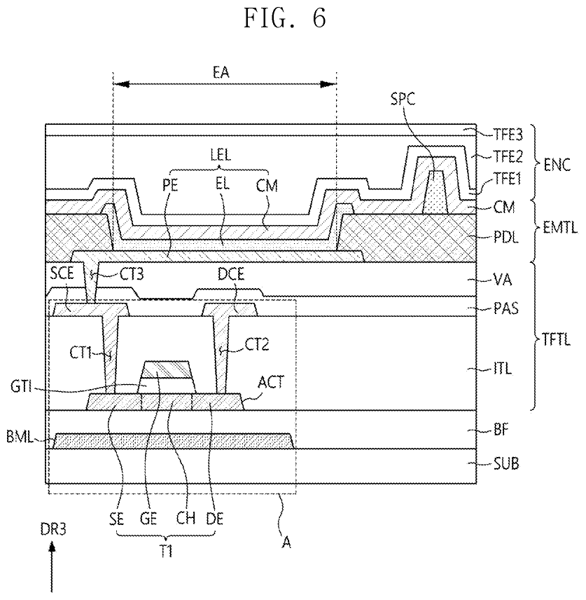

FIG. 6 is a schematic cross-sectional view of the display device according to an embodiment.

The display device according to an embodiment may include a substrate SUB, a light blocking layer BML, a buffer film BF, a thin film transistor layer TFTL, a light emitting element layer EMTL, and an encapsulation layer ENC as illustrated in FIG. 6. The light blocking layer, the buffer film BF, the thin film transistor layer TFTL, the light emitting element layer EMTL, and the encapsulation layer ENC may be sequentially disposed on the substrate SUB along the third direction DR3. For example, the thin film transistor layer TFTL may include the first transistor T1, the second transistor T2, and the third transistor T3 of FIG. 5 described above. FIG. 6 illustrates the first transistor T1 included in the thin film transistor layer TFTL as an example.

The substrate SUB may be a rigid substrate SUB or be a flexible substrate SUB that is bendable, foldable, rollable, or the like. The substrate SUB may be made of an insulating material such as glass, quartz, or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or combinations thereof. In another example, the substrate SUB may also include a metal material.

The light blocking layer BML may be disposed on the substrate SUB. The light blocking layer BML may be disposed on the substrate to overlap an active layer ACT, which will be described below. The light blocking layer BML may be formed of, for example, a metal material such as chromium (Cr) or molybdenum (Mo), or black ink or black dye. In case that the light blocking layer BML is formed of the metal material, the light blocking layer BML may receive a constant power. Thus, the light blocking layer BML does not electrically float, and electrical characteristics of the transistors T1, T2, and T3 on the light blocking layer BML may be stabilized. For example, performance degradation of the oxide-based transistors T1, T2, and T3 may be minimized. For example, since the oxide semiconductor is sensitive to light, fluctuations in the amount of current or the like may occur due to external light.

The buffer film BF may be disposed on the light blocking layer BML. The buffer film BF may be disposed on a surface (or an entire surface) of the substrate SUB including the light blocking layer BML. The buffer film BF may be a film for protecting the transistors of the thin film transistor layer TFTL and a light emitting layer EL of the light emitting element layer EMTL from moisture permeating through the substrate SUB, which is vulnerable to moisture permeation. The buffer film BF may include inorganic films that are alternately stacked with each other. For example, the buffer film BF may be formed as multiple films in which one or more inorganic films of a silicon nitride layer, a silicon oxynitride layer, a silicon oxide layer, a titanium oxide layer, and an aluminum oxide layer are alternately stacked with each other.

An active layer ACT may be disposed on the buffer film BF. The active layer ACT may be, for example, an oxide semiconductor. For example, the active layer ACT may be a semiconductor including indium-gallium-zinc-oxide (IGZO) or indium-gallium-zinc-tin oxide (IGZTO).

A gate insulating film GTI may be disposed on the active layer ACT. For example, the gate insulating film GTI may be disposed to overlap a channel region CH of the active layer ACT. The gate insulating film GTI may include at least one of tetraethoxysilane (TetraEthylOrthoSilicate, TEOS), silicon nitride (SiNₓ), and silicon oxide (SiO₂). As an example, the gate insulating film GTI may have a double film structure in which a silicon nitride film having a thickness of about 40 nm and a tetraethoxysilane film having a thickness of about 80 nm are sequentially stacked with each other.

A gate electrode GE may be disposed on the gate insulating film GTI. The gate electrode GE may be disposed on the gate insulating film GTI to overlap the channel region CH of the active layer ACT. The gate electrode GE may be made of aluminum (Al) or titanium (Ti). For example, the gate electrode GE may have a double or triple film structure in which aluminum (Al) and titanium (Ti) are stacked with each other.

An interlayer insulating film ITL may be disposed on the gate electrode GE. The interlayer insulating film ITL may be disposed on a surface (or an entire surface) of the substrate SUB including the gate electrode GE. The interlayer insulating film ITL may include an inorganic film, for example, a silicon nitride layer, a silicon oxynitride layer, a silicon oxide layer, a titanium oxide layer, or an aluminum oxide layer. For example, the interlayer insulating film ITL may include inorganic films.

A source connection electrode SCE and a drain connection electrode DCE may be disposed on the interlayer insulating film ITL. The source connection electrode SCE may be connected to a source electrode SE of the active layer ACT through a first contact hole CT1 penetrating (or passing) through the interlayer insulating film ITL. The drain connection electrode DCE may be connected to a drain electrode DE of the active layer ACT through a second contact hole CT2 penetrating (or passing) through the interlayer insulating film ITL. The source connection electrode SCE and the drain connection electrode DCE may be made of the same material as the gate electrode described above.

A passivation film PAS may be disposed on the source connection electrode SCE and the drain connection electrode DCE. The passivation film PAS may be disposed on the surface (or the entire surface) of the substrate SUB including the interlayer insulating film ITL. The passivation film PAS may be made of the same material as the interlayer insulating film ITL.

A planarization film VA may be disposed on the passivation film PAS. The passivation film PAS may be disposed on the surface (or the entire surface) of the substrate SUB including the planarization film VA. The planarization film VA may include an organic film made of an acrylic resin, an epoxy resin, a phenolic resin, a polyamide resin, or a polyimide resin.

A light emitting element layer EMTL including a pixel electrode PE may be disposed on the planarization film VA. The pixel electrode PE may be connected to the source connection electrode SCE through a third contact hole CT3 penetrating (or passing) through the planarization film VA. The pixel electrode PE may be connected to the source electrode SE of the active layer ACT through the source connection electrode SCE.

The above-described light emitting element layer EMTL may further include a light emitting element LEL and a bank PDL (or a pixel defining film) in addition to the above-described pixel electrode PE.

The light emitting element LEL may include a pixel electrode PE, a light emitting layer EL, and a common electrode CM. The light emitting area EA refers to an area in which the pixel electrode PE, the light emitting layer EL, and the common electrode CM are sequentially stacked with each other and holes from the pixel electrode PE and electrons from the common electrode CM are bonded to each other in the light emitting layer to emit light. For example, the pixel electrode PE may be an anode electrode of the light emitting element LEL, and the common electrode CM may be a cathode electrode of the light emitting element LEL.

In a top emission structure (or upper emission member) that emits light in a direction of the common electrode CM based on the light emitting layer EL, the pixel electrode may be formed as a single layer made of molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy may be an alloy of silver (Ag), palladium (Pd), and copper (Cu).

The bank PDL (or pixel defining film) may function to define the light emitting areas EA of the pixel. For example, the bank PDL may be disposed to expose a partial area of the pixel electrode PE on the planarization film VA. The bank PDL may cover an edge portion of the pixel electrode PE. The bank PDL may be formed as an organic film made of an acryl resin, an epoxy resin, a phenolic resin, a polyamide resin, or a polyimide resin.

A spacer SPC may be disposed on the bank PDL. The spacer SPC may function to support a mask during a process of fabricating the light emitting layer EL. The spacer SPC may be formed as an organic film made of an acryl resin, an epoxy resin, a phenolic resin, a polyamide resin, or a polyimide resin.

A light emitting layer EL may be formed on the pixel electrode PE. The light emitting layer EL may include an organic material to emit light of a predetermined color. For example, the light emitting layer EL may include a hole transporting layer, an organic material layer, and an electron transporting layer. The organic material layer may include a host and a dopant. The organic material layer may include a material that emits a predetermined light and may be formed of a phosphorescent material or a fluorescent material.

The pixels may include a first pixel emitting light of a first color through a first light emitting area, a second pixel emitting light of a second color through a second light emitting area, and a third pixel emitting light of a third color through a third light emitting area.

The organic material layer of the first light emitting layer of the first light emitting area that emits light of the first color may be a phosphorescent material including a host material including carbazole biphenyl (CBP) or mCP(1,3-bis (carbazol-9-yl), and including a dopant containing at least one of any one or more selected among PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and PtOEP(octaethylporphyrin platinum). In another example, the organic material layer of the first light emitting layer of the first light emitting area may be a fluorescent material including PBD:Eu(DBM)3(Phen) or perylene, but embodiments are not limited thereto.

The organic material layer of the second light emitting layer of the second light emitting area that emits light of the second color may be a phosphorescent material including a host material including CBP or mCP and a dopant material including fac tris(2-phenylpyridine)iridium (Ir(ppy)3). In another example, the organic material layer of the second light emitting layer of the second light emitting area that emits light of the second color may be a fluorescent material including tris(8-hydroxyquinolino)aluminum (Alq3), but embodiments are not limited thereto.

The organic material layer of the light emitting layer of the third light emitting area that emits light of the third color may be a phosphorescent material including a host material including CBP or mCP and including a dopant material including (4,6-F2ppy)2Irpic or L2BD111.

The common electrode CM may be disposed on the light emitting layer EL. For example, the common electrode CM may be disposed on the first, second, and third light emitting layers. The common electrode CM may be disposed to cover the first, second, and third light emitting layers. The common electrode CM may be a common layer commonly disposed on the first to third light emitting layers. A capping layer may be formed on the common electrode CM.

In the top emission structure (or upper emission member), the common electrode CM may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the common electrode CM is formed of the semi-transmissive conductive material, light emitting efficiency may be increased by a micro cavity.

The encapsulation layer ENC may be disposed on the light emitting element layer EMTL. The encapsulation layer ENC may include at least one inorganic film (e.g., TFE1 or TFE3) to prevent oxygen or moisture from permeating into the light emitting element layer EMTL. For example, the encapsulation layer ENC may include at least one organic film to protect the light emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked with each other. The encapsulation organic film TFE2 may be an organic film made of an acrylic resin, an epoxy resin, a phenolic resin, a polyamide resin, or a polyimide resin.

In another example, a barrier film may be further disposed between the substrate SUB and the light blocking layer BML described above. The barrier film may be a film for protecting the transistors T1 to T3 of the thin film transistor layer TFTL and the light emitting layer EL of the light emitting element layer EMTL from moisture permeating through the substrate SUB vulnerable to moisture permeation. The barrier film may include inorganic films that are alternately stacked with each other. For example, the barrier film may be formed as multiple films in which one or more inorganic films of a silicon nitride layer, a silicon oxynitride layer, a silicon oxide layer, a titanium oxide layer, and an aluminum oxide layer are alternately stacked with each other.

FIG. 7 is an enlarged schematic view of portion A of FIG. 6.

The active layer of each transistor (e.g., the first transistor T1) may include a first sub-active layer SACT1, a second sub-active layer SACT2, and a third sub-active layer SACT3 sequentially stacked with each other in the third direction DR3, as illustrated in FIG. 7. For example, since the active layer ACT may include a first sub-active area SA1, a second sub-active area SA2, and a third sub-active area SA3, the first sub-active layer SACT1 may be disposed in the first sub-active area SA1, the second sub-active layer SACT2 may be disposed in the second sub-active area SA2, and the third sub-active layer SACT3 may be disposed in the third sub-active area SA3.

The first sub-active layer SACT1 may be in contact with (e.g., in direct contact with) the buffer film BF. For example, a lower side surface of the first sub-active layer SACT1 may be in contact with (e.g., in direct contact with) an upper side surface of the buffer film BF.

The third sub-active layer SACT3 may be in contact with (e.g., in direct contact with) the gate insulating film GTI. For example, an upper side surface of the third sub-active layer SACT3 may be in contact with (e.g., in direct contact with) a lower side surface of the gate insulating film GTI.

The second sub-active layer SACT2 may be disposed between the first sub-active layer SACT1 and the third sub-active layer SACT3.

The first sub-active layer SACT1, the second sub-active layer SACT2, and the third sub-active layer SACT3 may be integral with each other. For example, the first sub-active layer SACT1 and the second sub-active layer SACT2 may be integral with each other without an interface therebetween, and the second sub-active layer SACT2 and the third sub-active layer SACT3 may be integral with each other without an interface therebetween. In another example, a first interface IF1 disposed between the first sub-active layer SACT1 and the second sub-active layer SACT2 may exist (or be formed/disposed), and/or a second interface IF2 disposed between the second sub-active layer SACT2 and the third sub-active layer SACT3 may exist (or be formed/disposed). For example, a dotted line between the first sub-active layer SACT1 and the second sub-active layer SACT2 in FIG. 7 may be the first interface IF1 disposed between the first sub-active layer SACT1 and the second sub-active layer SACT2, and a dotted line between the second sub-active layer SACT2 and the third sub-active layer SACT3 in FIG. 7 may be the second interface IF2 disposed between the second sub-active layer SACT2 and the third sub-active layer SACT3.

At least two sub-active layers among the first sub-active layer SACT1, the second sub-active layer SACT2, and the third sub-active layer SACT3 may have different oxygen (O₂) contents. For example, the first sub-active layer SACT1 and the third sub-active layer SACT3 in contact with (e.g., in direct contact with) other material layers in a vertical direction (e.g., the third direction DR3) may contain a smaller amount of oxygen (O₂) than the second sub-active layer SACT2 disposed between the first sub-active layer SACT1 and the second sub-active layer SACT2. For example, the first sub-active layer SACT1 forming a third interface IF3 by being in contact with (e.g., in direct contact with) the buffer film BF may contain a smaller amount of oxygen (O₂) than the second sub-active layer SACT2, and the third sub-active layer SACT3 forming a fourth interface IF4 by being in contact with (e.g., in direct contact with) the gate insulating film GTI may contain a smaller amount of oxygen (O₂) than the second sub-active layer SACT2. As an example, the oxygen (O₂) content of the first sub-active layer SACT1 may be smaller than the oxygen (O₂) content of the second sub-active layer SACT2, and the oxygen (O₂) content of the third sub-active layer SACT3 may be smaller than the oxygen (O₂) content of the second sub-active layer SACT2. For example, among the first to third sub-active layers SACT1 to SACT3, the third sub-active layer SACT3 positioned farthest from the substrate SUB may contain the smallest amount of oxygen (O₂). For example, the oxygen (O₂) content of the third sub-active layer SACT3 may be smaller than the oxygen (O₂) content of the first sub-active layer SACT1, or the oxygen (O₂) content of the third sub-active layer SACT3 may be smaller than the oxygen (O₂) content of the second sub-active layer SACT2. For example, a flow rate of oxygen (O₂) gas used in a process of forming (or depositing) the third sub-active layer SACT3 may be zero. For example, the flow rate of the oxygen (O₂) gas may refer to a ratio of the oxygen (O₂) gas to a total amount of gases (e.g., argon (Ar) gas and oxygen (O₂) gas) used to form the third sub-active material layer SAM3.

For example, at least two sub-active layers among the first sub-active layer SACT1, the second sub-active layer SACT2, and the third sub-active layer SACT3 may have different hydrogen (H) contents. For example, the hydrogen (H) content of each of the sub-active layers SACT1 to SACT3 may be different according to the flow rate of oxygen (O₂) gas used in the process of forming each of the sub-active layers SACT1 to SACT3. For example, as the flow rate of oxygen (O₂) gas used in the process of forming each of the sub-active layers SACT1 to SACT3 increases, the hydrogen (H) content of each of the sub-active layers SACT1 to SACT3 may decrease. As an example, the second sub-active layer among the first to third sub-active layers SACT1 to SACT3 may have the smallest hydrogen (H) content.

For example, at least two sub-active layers among the first sub-active layer SACT1, the second sub-active layer SACT2, and the third sub-active layer SACT3 may have different hydroxide (OH—) contents. For example, the hydroxide (OH—) content of each of the sub-active layers SACT1 to SACT3 may be different according to the flow rate of oxygen (O₂) gas used in the process of forming each of the sub-active layers SACT1 to SACT3. For example, as the flow rate of oxygen (O₂) gas used in the process of forming each of the sub-active layers SACT1 to SACT3 increases, the hydroxide (OH—) content of each of the sub-active layers SACT1 to SACT3 may decrease. As an example, the second sub-active layer among the first to third sub-active layers SACT1 to SACT3 may have the smallest hydroxide (OH—) content.

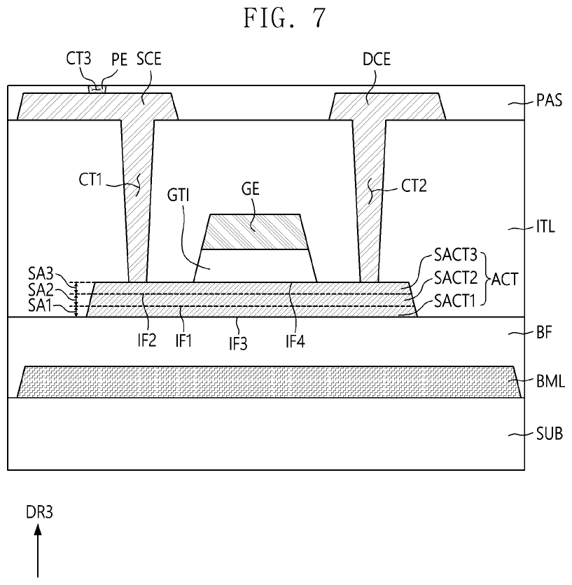

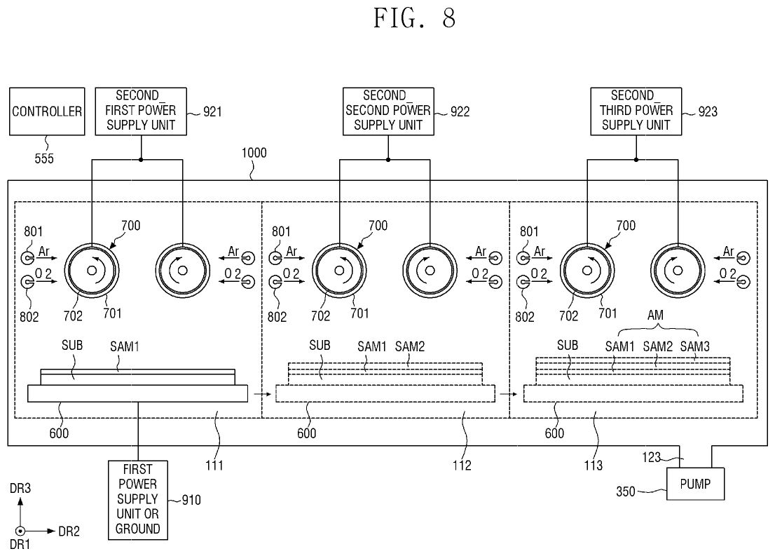

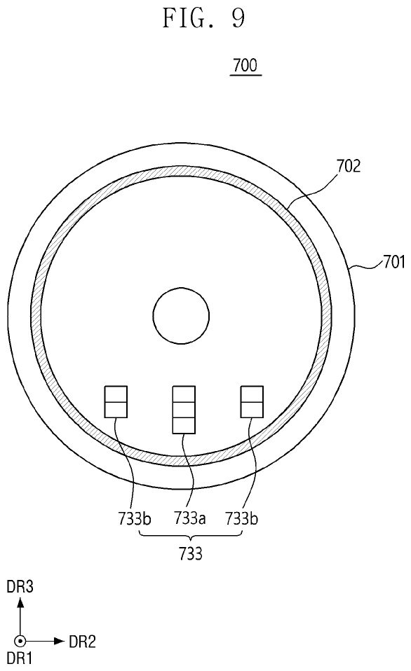

FIG. 8 is a schematic diagram of a sputtering device according to an embodiment, and FIG. 9 is a schematic diagram of a target portion according to an embodiment.

The sputtering device may form a thin film on the substrate SUB through a reactive sputtering phenomenon by introducing (or supplying) a sputtering gas (e.g., argon (Ar) gas) and a reactive gas (e.g., oxygen (O₂) gas). For example, in the reactive sputtering, the reactive gas may be supplied into a chamber 1000 (or a process chamber 1000) such that the reactive gas may be reacted with atoms emitted from a target 701, thereby producing a film sputtered directly on the substrate SUB or sputtered on the substrate SUB by being reacted again with the target 701. For example, the reactive gas may directly react with the atoms emitted from the target 701 and be deposited on the substrate SUB in a compound state.

As illustrated in FIG. 8, the sputtering device may include a chamber 1000, a carrier 600, a first power supply unit 910, second power supply units 921, 922, and 923, and a controller 555.

The chamber 1000 may include deposition areas 111, 112, and 113. For example, the chamber 1000 may include a first deposition area 111, a second deposition area 112, and a third deposition area 113, as illustrated in FIG. 8. Various gases may be introduced (or supplied) into each of the deposition areas 111, 112, and 113. For example, argon (Ar) may be introduced (or supplied) from the outside into the first deposition area 111 to form plasma during the deposition process, and at least one of oxygen (O₂) and nitrogen (N₂) may be supplied from the outside into the first deposition area 111 to determine properties of a layer deposited on the substrate SUB.

For example, the carrier 600 may be disposed inside the chamber 1000. The carrier 600 may support the substrate SUB and move the substrate SUB to different deposition areas. For example, the carrier 600 may move along the second direction DR2 inside the chamber 1000. As a specific example, the carrier 600 may move from the outside to the first deposition area 111, or may move from the first deposition area 111 to the second deposition area 112, or may move from the second deposition area 112 to the third deposition area 113. The carrier 600 may support the substrate SUB so that the substrate SUB may not move or shake while the deposition process for the substrate SUB is performed. For example, the carrier 600 may include, for example, a clamp for fixing the substrate SUB. For example, for adsorption between the carrier 600 and the substrate SUB, the carrier 600 may also include one or more adsorption holes.

The carrier 600 may be connected to the first power supply unit 910. A first power from the first power supply unit 910 may be applied to the carrier 600. The carrier 600 may function as an anode electrode of a sputtering device. In another example, the first power supply unit 910 may also be connected to the chamber 1000 instead of the carrier 600. For example, the first power supply unit 910 may be connected to the chamber 1000. For example, the power from the first power supply unit 910 may be applied to the chamber 1000. The carrier 600 may be made of a material having high heat resistance and durability to prevent deterioration and damage caused by heat during the deposition process.

The first power from the first power supply unit 910 may be direct current (DC) power (e.g., DC voltage or DC current) or alternating (AC) power (e.g., AC voltage or AC current).

In another example, the carrier 600 may also be connected to a ground instead of the first power from the first power supply unit 910. In another example, the ground may also be connected to the chamber 1000 instead of the carrier 600.

The substrate SUB may be moved with being mounted on the carrier 600 in a state of being erected. For example, in FIG. 8, the first direction DR1 or a reverse direction to the first direction DR1 (hereinafter, referred to as a first reverse direction) is a direction of gravity, and the substrate SUB may be moved in a state of being erected in the direction of gravity. Accordingly, accumulation of by-products on the substrate SUB during the deposition process may be prevented.

The target portion 700 may be disposed on an opposite side of the carrier 600 inside each deposition area of the chamber 1000. Two target portions 700 may be disposed in pairs in each of the deposition areas 111, 112, and 113. A pair of target portions 700 may be disposed to face each other. The target portion 700 may be installed to be rotatable.

The target portion 700 may include a target 701 and a support portion 702 (or a backing plate) capable of supporting the target 701.

The target 701 may be deposited on the substrate SUB. The target 701 and the deposition material may be made of the same material. For example, the target 701 may be variously formed of aluminum (Al), aluminum alloy (AlNd), chromium (Cr), molybdenum (Mo), indium-gallium-zinc (Indium-Gallium-Zinc), indium-gallium-zinc-tin, or the like, according to a film to be formed on the substrate SUB. As another example, the target 701 may include oxide of indium (In), gallium (Ga), and zinc (Zinc) (e.g., indium-gallium-zinc-oxide (IGZO)). For example, the target 701 may have a solid form or a powder form.

The support portion 702 may be disposed inside the target portion 700 to support the target 701. For example, the support portion 702 may maintain a constant temperature of the target 701 during the deposition process. Each support portion 702 of each of the deposition areas 111, 112, and 113 may be connected to the second power supply units 921, 922, and 923. A second power from the second power supply units 921, 922, and 923 may be applied to each support portion 702. Each support portion 702 may function as a cathode electrode of the sputtering device. In another example, the support portion 702 may be omitted, and the second power supply units 921, 922, and 923 may be connected (e.g., directly connected) to each target 701. As in the example illustrated in FIG. 8, the target portion 700 may have a cylindrical shape with an empty interior. For example, the support portion 702 inside the target portion 700 may also have a cylindrical shape with an empty interior. However, the shape of the target portion 700 is not limited thereto. For example, the target portion 700 may have a shape of a bar extending in a direction.

The second power from the second power supply units 921, 922, and 923 may be direct current (DC) power (e.g., DC voltage or DC current) or alternating (AC) power (e.g., AC voltage or AC current).

The second power supply units 921, 922, and 923 may include a second_first power supply unit 921, a second_second power supply unit 922, and a second_third power supply unit 923. The second power supply units 921, 922, and 923 may be individually connected to the target portion 700 of each of the deposition areas 111, 112, and 113. For example, each support portion 702 (or each target 701) of the target portions 700 of the first deposition area 111 may be connected to the second_first power supply unit 921, each support portion 702 (or each target 701) of the target portions 700 of the second deposition area 112 may be connected to the second_second power supply unit 922, and each support portion 702 (or each target 701) of the target portions 700 of the third deposition area 113 may be connected to the second_third power supply unit 923. Accordingly, the target portions 700 of each of the deposition areas 111, 112, and 113 may be supplied with second power having different sizes. For example, the second power applied to the target portions 700 of the first deposition area 111, the second power applied to the target portions 700 of the second deposition area 112, and the second power applied to the target portions 700 of the third deposition area 113 may be controlled independently of each other.

For example, as illustrated in FIG. 9, the target portion 700 may further include a magnet unit 733 therein. The magnet unit 733 may adjust deposition efficiency by forming a magnetic field and adjusting a path and a distribution of plasma of the sputtering device. The magnet unit 733 may not be connected to the target 701 and the support portion 702. For example, the magnet unit 733 may not rotate while the deposition process is performed while the target 701 rotates. The magnet unit 733 may generate a magnetic field capable of controlling plasma discharge. The magnet unit 733 may include, for example, a first magnet unit 733a and second magnet units 733b disposed on sides (e.g., opposite sides) of the first magnet unit 733a. For example, as the first magnet unit 733a and a pair of second magnet units 733b are disposed to have polarities opposite to each other, the magnetic field generated by the magnet unit 733 may be concentrated on a portion of the target 701, and thus the plasma discharge may also be controlled to be concentrated on a portion of the target 701.

Referring to FIG. 8, a first gas jetting unit 801 and a second gas jetting unit 802 may be disposed in the chamber 1000. For example, the first gas jetting unit 801 and the second gas jetting unit 802 may be disposed in each of the deposition areas 111, 112, and 113 in the chamber 1000. The first gas jetting unit 801 and the second gas jetting unit 802 may be disposed within each of the deposition areas 111, 112, and 113 to face the target portion 700 within the deposition area. The first gas jetting unit 801 and the second gas jetting unit 802 may jet (or inject) sputtering gas, for example, oxygen (O₂) gas and argon (Ar) gas. As an example, the first gas jetting unit 801 may jet (or inject) argon (Ar) gas, and the second gas jetting unit 802 may jet (or inject) oxygen (O₂) gas.

A pump 350 may be connected to an exhaust port 123 of the chamber 1000 to adjust a pressure of the chamber 1000. Each pump 350 may be a vacuum pump. For example, each pump 350 may be a cryo pump.

The controller 555 may control the carrier 600, the first power supply unit 910, the second power supply unit 921, 922, and 923, the first gas jetting unit 801 and the second gas jetting unit 802, and the pump 350. For example, the controller 555 may control a movement of the carrier 600, the magnitude of power from each of the power supply units 910 and 921, 922, and 923, the amount of gas (e.g., argon gas (Ar) and oxygen (O₂) gas) jetted from each of the gas jetting units 801 and 802, and a displacement of the pump 350.

A method of fabricating a display device by using such a sputtering device will be described below.

For example, the substrate SUB may be loaded into the chamber 1000 of the sputtering apparatus by the carrier 600. For example, a light blocking layer BML and a buffer film BF may be formed on the substrate SUB. For example, the light blocking layer BML and the buffer film BF may be formed on the substrate SUB before the substrate SUB is loaded into the chamber 1000. In the chamber 1000, sub-active material layers SAM1, SAM2, and SAM3 to be formed as the active layer ACT may be continuously deposited on the substrate SUB.

The substrate SUB loaded into the chamber 1000 may be moved to the first deposition area 111 by the carrier 600. In the first deposition area 111, a first sub-active material layer SAM1 corresponding to the first sub-active layer SACT1 of the active layer ACT may be deposited. For example, in the first deposition area 111, the first sub-active material layer SAM1 may be deposited on the buffer film BF of the substrate SUB. For example, a process of depositing the first sub-active material layer SAM1 will be described below. For example, in case that the substrate SUB is disposed within the first deposition area 111, the first gas jetting unit 801 and the second gas jetting unit 802 in the first deposition area 111 may jet (or inject) oxygen (O₂) gas and argon (Ar) gas toward the targets 701 in the first deposition area 111. For example, argon (Ar) gas may be provided as a sputter gas forming plasma, and oxygen (O₂) may be provided as a reactive gas for forming an oxide film on a surface of the target 701 and forming an oxide film on the substrate SUB. In this state, in case that a discharge is caused by using the target 701 in the first deposition area 111 as a cathode and the substrate SUB, which is a sputtering target, as an anode, argon (Ar) ions are generated from the argon (Ar) gas, the argon (Ar) ions collide with the target 701 to scatter particles of the target 701, and the scattered particles may be deposited on the substrate SUB to form a thin film. For example, an oxide film may be formed on the surface of the target 701 by oxygen (O₂), which is the reactive gas, and a portion of the oxide film may also form a portion of the thin film with being deposited on the substrate SUB. Accordingly, the thin film on the substrate SUB may include a body component (e.g., indium-gallium-zinc) and an oxide film component of the target 701 provided in the first deposition area 111. For example, since the thin film as the first sub-active material layer SAM1 may be made of indium-gallium-zinc-oxide, the first sub-active material layer SAM1 may be formed on the buffer film BF. For example, in a state in which a flow rate of oxygen (O₂) gas in the first deposition area 111, a power in the first deposition area 111, and a pressure inside the chamber 1000 are preset, a deposition process for the first sub-active material layer SAM1 may be performed. For example, the flow rate of the oxygen (O₂) gas in the first deposition area 111 may refer to a ratio of the oxygen (O₂) gas to a total amount of gases (e.g., argon (Ar) gas and oxygen (O₂) gas) used to form the first sub-active material layer SAM1. The flow rate of the oxygen (O₂) gas in the first deposition area 111 may be adjusted by, for example, controlling the amount of oxygen (O₂) gas jetted from the second gas jetting unit 802 of the first deposition area 111. The power in the first deposition area 111 may be adjusted based on a first power supplied to the carrier 600 and a second power supplied to the target portion 700 of the first deposition area 111. For example, the power in the first deposition area 111 may be adjusted by, for example, the first power from the first power supply unit 910 and the second power from the second_first power supply unit 921. For example, in case that the first power corresponds to the ground (or in case that the carrier 600 is connected to the ground), the power in the first deposition area 111 may be adjusted according to the magnitude of the second power from the second_first power supply unit 921. The pressure inside the chamber 1000 may be the pressure inside the chamber 1000 in case that the deposition process for the first sub-active material layer SAM1 is performed. The pressure inside the chamber 1000 may be adjusted by, for example, the pump 350 connected to the exhaust port 123 of the chamber 1000.

For example, in case that the deposition process is performed in the first deposition area 111, the first and second gas jetting units 801 and 802 of the remaining deposition areas (e.g., the second deposition area 112 and the third deposition area 113) within the chamber 1000 may not jet the corresponding gas. For example, in case that the deposition process is performed in the first deposition area 111, the second power supply units 922 and 923 connected to the remaining deposition areas (e.g., the second deposition area 112 and the third deposition area 113) within the chamber 1000 may not supply the power. In another example, in case that the deposition process is performed in the first deposition area 111, the first and second gas jetting units 801 and 802 of the remaining deposition areas (e.g., the second deposition area 112 and the third deposition area 113) within the chamber 1000 may also jet (or inject) the corresponding gas. For example, in case that the deposition process is performed in the first deposition area 111, the second power supply units 922 and 923 connected to the remaining deposition areas (e.g., the second deposition area 112 and the third deposition area 113) within the chamber 1000 may also supply the power.

Thereafter, the substrate SUB on which the first sub-active material layer SAM1 is deposited may be moved from the first deposition area 111 to the second deposition area 112 by the carrier 600. In the second deposition area 112, a second sub-active material layer SAM2 corresponding to the second sub-active layer SACT2 of the active layer ACT may be deposited. For example, in the second deposition area 112, the second sub-active material layer SAM2 may be deposited on the first sub-active material layer SAM1 of the substrate SUB. For example, a process of depositing the second sub-active material layer SAM2 will be described below. For example, in case that the substrate SUB is disposed within the second deposition area 112, the first and second gas jetting units 801 and 802 in the second deposition area 112 may jet (or inject) oxygen (O₂) gas and argon (Ar) gas toward the targets 701 in the second deposition area 112. In this state, in case that a discharge is caused by using the target 701 in the second deposition area 112 as a cathode and the substrate SUB, which is a sputtering target, as an anode, argon (Ar) ions are generated from the argon (Ar) gas, the argon (Ar) ions collide with the target 701 to scatter particles of the target 701, and the scattered particles may be deposited on the substrate SUB to form a thin film. For example, an oxide film may be formed on the surface of the target 701 by oxygen (O₂), which is the reactive gas, and a portion of the oxide film may also form a portion of the thin film with being deposited on the substrate SUB. Accordingly, the thin film on the substrate SUB may include a body component (e.g., indium-gallium-zinc) and an oxide film component of the target 701 provided in the second deposition area 112. For example, since the thin film as the second sub-active material layer SAM2 may be made of indium-gallium-zinc-oxide, the second sub-active material layer SAM2 may be formed on the first sub-active material layer SAM1. For example, in a state in which a flow rate of oxygen (O₂) gas in the second deposition area 112, a power in the second deposition area 112, and a pressure inside the chamber 1000 are preset, a deposition process for the second sub-active material layer SAM2 may be performed. For example, the flow rate of the oxygen (O₂) gas in the second deposition area 112 may refer to a ratio of the oxygen (O₂) gas to a total amount of gases (e.g., argon (Ar) gas and oxygen (O₂) gas) used to form the second sub-active material layer SAM2. The flow rate of the oxygen (O₂) gas in the second deposition area 112 may be adjusted by, for example, controlling the amount of oxygen (O₂) gas jetted from the second gas jetting unit 802 of the second deposition area 112. The power in the second deposition area 112 may be adjusted based on a first power supplied to the carrier 600 and a second power supplied to the target portion 700 of the second deposition area 112. For example, the power in the second deposition area 112 may be adjusted by, for example, the first power from the first power supply unit 910 and the second power from the second_second power supply unit 922. For example, in case that the first power corresponds to the ground (or in case that the carrier 600 is connected to the ground), the power in the second deposition area 112 may be adjusted according to the magnitude of the second power from the second_second power supply unit 922. The pressure inside the chamber 1000 may be the pressure inside the chamber 1000 in case that the deposition process for the second sub-active material layer SAM2 is performed.

For example, in case that the deposition process is performed in the second deposition area 112, the first and second gas jetting units 801 and 802 of the remaining deposition areas (e.g., the first deposition area 111 and the third deposition area 113) within the chamber 1000 may not jet (or inject) the corresponding gas. For example, in case that the deposition process is performed in the second deposition area 112, the second power supply units 921 and 923 connected to the remaining deposition areas (e.g., the first deposition area 111 and the third deposition area 113) within the chamber 1000 may not supply the power. In another example, in case that the deposition process is performed in the second deposition area 112, the first and second gas jetting units 801 and 802 of the remaining deposition areas (e.g., the first deposition area 111 and the third deposition area 113) within the chamber 1000 may also jet (or inject) the corresponding gas. For example, in case that the deposition process is performed in the second deposition area 112, the second power supply units 921 and 923 connected to the remaining deposition areas (e.g., the first deposition area 111 and the third deposition area 113) within the chamber 1000 may also supply the power.

Subsequently, the substrate SUB on which the first and second sub-active material layers SAM1 and SAM2 are deposited may be moved from the second deposition area 112 to the third deposition area 113 by the carrier 600. In the third deposition area 113, a third sub-active material layer SAM3 corresponding to the third sub-active layer SACT3 of the active layer ACT may be deposited. For example, in the third deposition area 113, the third sub-active material layer SAM3 may be deposited on the second sub-active material layer SAM2 of the substrate SUB. For example, a process of depositing the third sub-active material layer SAM3 will be described below. For example, in case that the substrate SUB is disposed within the third deposition area 113, the first and second gas jetting units 801 and 802 in the third deposition area 113 may jet (or inject) oxygen (O₂) gas and argon (Ar) gas toward the targets 701 in the third deposition area 113. In this state, in case that a discharge is caused by using the target 701 in the third deposition area 113 as a cathode and the substrate SUB, which is a sputtering target, as an anode, argon (Ar) ions are generated from the argon (Ar) gas, the argon (Ar) ions collide with the target 701 to scatter particles of the target 701, and the scattered particles may be deposited on the substrate SUB to form a thin film. For example, an oxide film may be formed on the surface of the target 701 by oxygen (O₂), which is the reactive gas, and a portion of the oxide film may also form a portion of the thin film with being deposited on the substrate SUB. Accordingly, the thin film on the substrate SUB may include a body component (e.g., indium-gallium-zinc) and an oxide film component of the target 701 provided in the third deposition area 113. For example, since the thin film as the third sub-active material layer SAM3 may be made of indium-gallium-zinc-oxide, the third sub-active material layer SAM3 may be formed on the second sub-active material layer SAM2. For example, in a state in which a flow rate of oxygen (O₂) gas in the third deposition area 113, a power in the third deposition area 113, and a pressure inside the chamber 1000 are preset, a deposition process for the third sub-active material layer SAM3 may be performed. For example, the flow rate of the oxygen (O₂) gas in the third deposition area 113 may refer to a ratio of the oxygen (O₂) gas to a total amount of gases (e.g., argon (Ar) gas and oxygen (O₂) gas) used to form the third sub-active material layer SAM3. The flow rate of the oxygen (O₂) gas in the third deposition area 113 may be adjusted by, for example, controlling the amount of oxygen (O₂) gas jetted from the second gas jetting unit 802 of the third deposition area 113. The power in the third deposition area 113 may be adjusted based on a first power supplied to the carrier 600 and a second power supplied to the target portion 700 of the third deposition area 113. For example, the power in the third deposition area 113 may be adjusted by, for example, the first power from the first power supply unit 910 and the second power from the second_third power supply unit 923. For example, in case that the first power corresponds to the ground (or in case that the carrier 600 is connected to the ground), the power in the third deposition area 113 may be adjusted according to the magnitude of the second power from the second_third power supply unit 923. The pressure inside the chamber 1000 may be the pressure inside the chamber 1000 in case that the deposition process for the third sub-active material layer SAM3 is performed.

For example, in case that the deposition process is performed in the third deposition area 113, the first and second gas jetting units 801 and 802 of the remaining deposition areas (e.g., the first deposition area 111 and the second deposition area 112) within the chamber 1000 may not jet (or inject) the corresponding gas. For example, in case that the deposition process is performed in the third deposition area 113, the second power supply units 921 and 922 connected to the remaining deposition areas (e.g., the first deposition area 111 and the second deposition area 112) within the chamber 1000 may not supply the power. In another example, in case that the deposition process is performed in the third deposition area 113, the first and second gas jetting units 801 and 802 of the remaining deposition areas (e.g., the first deposition area 111 and the second deposition area 112) within the chamber 1000 may also jet (or inject) the corresponding gas. For example, in case that the deposition process is performed in the third deposition area 113, the second power supply units 921 and 922 connected to the remaining deposition areas (e.g., the first deposition area 111 and the second deposition area 112) within the chamber 1000 may also supply the power.

As the substrate SUB loaded into the chamber 1000 passes sequentially through the first deposition area 111, the second deposition area 112, and the third deposition area 113, the first sub-active material layer SAM1, the second sub-active material layer SAM2, and the third sub-active material layer SAM3 may be formed on the substrate SUB. For example, in case that the substrate SUB passes through the first deposition area 111, the second deposition area 112, and the third deposition area 113, the substrate SUB continuously passes through the first deposition area 111, the second deposition area 112, and the third deposition area 113 without stopping in the middle. Therefore, an active material layer AM including the sub-active material layers SAM1 to SAM3 may be formed through substantially one deposition process in one substantially identical chamber 1000. For example, the active material layer AM including the sub-active material layers SAM1 to SAM3 may be formed through a single deposition process performed in the same chamber 1000.

For example, the first sub-active material layer SAM1, the second sub-active material layer SAM2, and the third sub-active material layer SAM3 deposited on the substrate SUB through the deposition processes in the first deposition area 111, the second deposition area 112, and the third deposition area 113 may be integral with each other. For example, the first sub-active material layer SAM1 and the second sub-active material layer SAM2 may be integral with each other without an interface therebetween, and the second sub-active material layer SAM2 and the third sub-active material layer SAM3 may be integral with each other without an interface therebetween. In another example, a first interface IF1 disposed between the first sub-active material layer SAM1 and the second sub-active material layer SAM2 may exist (or be formed/disposed), or a second interface IF2 disposed between the second sub-active material layer SAM2 and the third sub-active material layer SAM3 may exist (or be formed/disposed).

The substrate SUB on which the active material layer AM is deposited may be discharged to the outside of the chamber 1000 by the carrier 600. Thereafter, the substrate SUB discharged to the outside of the chamber 1000 may be moved to a processing equipment for a next process, for example, a photolithography process and an etching process. In case that the active material layer AM is patterned through the photolithography process and the etching process, the above-described active layer ACT may be formed.

For example, the flow rate of oxygen (O₂) gas in each of the deposition areas and the magnitude of power in each of the deposition areas 111, 112, and 113 may be individually controlled. For example, the flow rate of oxygen (O₂) gas and the magnitude of power may be independently controlled for each of the deposition areas 111, 112, and 113. For example, at least two deposition processes among the deposition processes described above may be performed in an atmosphere provided with oxygen (O₂) gas having different flow rates and power having different magnitudes. Accordingly, threshold voltage characteristics and hysteresis characteristics of the active layer ACT may be precisely controlled. For example, in case that the flow rate of oxygen (O₂) gas and the power in each of the deposition areas 111, 112, and 113 are individually or independently adjusted, the hydrogen (H) content and hydroxide (OH—) content of each of the sub-active material layers SAM1 to SAM3 may be individually or independently adjusted. Accordingly, the magnitude of threshold voltage and hysteresis characteristics of an oxide semiconductor transistor including the sub-active material layers SAM1 to SAM3 may be precisely controlled. Therefore, reliability of the transistor including the oxide semiconductor may be improved.

As an example, a flow rate of oxygen (O₂) gas in case that the second active material layer SAM2 is formed (e.g., deposited) in the second deposition area 112 may be greater than a flow rate of oxygen (O₂) gas in case that the first active material layer SAM1 is formed (e.g., deposited) in the first deposition area 111. For example, the flow rate of oxygen (O₂) gas in case that the second active material layer SAM2 is formed (e.g., deposited) in the second deposition area 112 may be greater than a flow rate of oxygen (O₂) gas in case that the third active material layer SAM3 is formed (e.g., deposited) in the third deposition area 113. For example, the flow rate of oxygen (O₂) gas in case that the second active material layer SAM2 is formed (e.g., deposited) in the second deposition area 112 may be greater than about 35%.

Additionally or alternatively, a power in case that the second active material layer SAM2 is formed (e.g., deposited) in the second deposition area 112 may be smaller than a power in case that the first active material layer SAM1 is formed (e.g., deposited) in the first deposition area 111. For example, the power in case that the second active material layer SAM2 is formed (e.g., deposited) in the second deposition area 112 may be smaller than a power in case that the third active material layer SAM3 is formed (e.g., deposited) in the third deposition area 113. For example, the power in case that the second active material layer SAM2 is formed (e.g., deposited) in the second deposition area 112 may be smaller than about 10.2 kW.

Additionally or alternatively, a pressure, in which the second active material layer SAM2 is formed (e.g., deposited) in the second deposition area 112, may be greater than a pressure, in which the first active material layer SAM1 is formed (e.g., deposited) in the first deposition area 111. For example, the pressure, in which the second active material layer SAM2 is formed (e.g., deposited) in the second deposition area 112, may be greater than a pressure, in which the third active material layer SAM3 is formed (e.g., deposited) in the third deposition area 113. For example, the pressure in which the second active material layer SAM2 is formed (e.g., deposited) in the second deposition area 112, may be greater than about 0.6 Pa.

The active layer ACT fabricated according to the above-described fabricating method may include the first sub-active layer SACT1, the second sub-active layer SACT2, and the third sub-active layer SACT3 sequentially stacked with each other on the substrate SUB along the third direction DR3. For example, since the active layer ACT may include the first sub-active area SA1, the second sub-active area SA2, and the third sub-active area SA3, the first sub-active layer SACT1 may be disposed in the first sub-active area SA1, and the second sub-active layer SACT2 may be disposed in the second sub-active area SA2, and the third sub-active layer SACT3 may be disposed in the third sub-active area SA3.

The first sub-active layer SACT1 may be a layer formed based on the first sub-active material layer SAM1 described above, the second sub-active layer SACT2 may be a layer formed based on the second sub-active material layer SAM2 described above, and the third sub-active layer SACT3 may be a layer formed based on the third sub-active material layer SAM3 described above.

At least two sub-active layers among the first sub-active layer SACT1, the second sub-active layer SACT2, and the third sub-active layer SACT3 formed by the above-described deposition method may have different oxygen (O₂) contents. A difference in the oxygen (O₂) content between the sub-active layers SACT1 to SACT3 may be due to, for example, at least one of a difference in the flow rate of oxygen (O₂) gas introduced (or supplied) during the process of forming the sub-active material layers SAM1 to SAM3 and a difference in the power. For example, the oxygen (O₂) content in the sub-active layer may be proportional to the flow rate of oxygen (O₂) gas introduced (or supplied) during the deposition process of the sub-active material layer. For example, as the flow rate of the oxygen (O₂) gas introduced (or supplied) during the deposition process of the first sub-active material layer SAM1 increases, the first sub-active layer SACT1 may contain a larger amount of oxygen (O₂). As another example, the hydrogen (H) content of the sub-active layer may be inversely proportional to the power introduced (or supplied) during the deposition process of the sub-active material layer. For example, as the power introduced (or supplied) during the deposition process of the first sub-active material layer SAM1 increases, the first sub-active layer SACT1 may contain a smaller amount of hydrogen (H). For example, as the power increases, a speed of argon (Ar) particles colliding with the target 701 increases, and accordingly, a speed of particles deposited on the substrate SUB also increases. As a result, a density of a film (e.g., a sub-active material layer) formed by such particles may increase, and thus the hydrogen (H) content in the film may decrease.

For example, at least two sub-active layers among the first sub-active layer SACT1, the second sub-active layer SACT2, and the third sub-active layer SACT3 formed by the above-described deposition method may have different hydrogen (H) contents. A difference in the hydrogen (H) content between the sub-active layers SACT1 to SACT3 may be due to, for example, at least one of a difference in the flow rate of oxygen (O₂) gas introduced (or supplied) during the process of forming the sub-active material layers SAM1 to SAM3 and a difference in the power. As an example, the hydrogen (H) content in the sub-active layer may be inversely proportional to the flow rate of oxygen (O₂) gas introduced (or supplied) during the deposition process of the sub-active material layer. For example, as the flow rate of the oxygen (O₂) gas introduced (or supplied) during the deposition process of the first sub-active material layer SAM1 increases, the first sub-active layer SACT1 may contain a smaller amount of hydrogen. As still another example, the hydrogen (H) content of the sub-active layer may be inversely proportional to the power introduced (or supplied) during the deposition process of the sub-active material layer. For example, as the power introduced (or supplied) during the deposition process of the first sub-active material layer SAM1 increases, the first sub-active layer SACT1 may contain a smaller amount of hydrogen. For example, as described above, as the power increases, the density of the film (e.g., the sub-active material layer) increases, and thus the hydrogen (H) content in the film may decrease.

For example, at least two sub-active layers among the first sub-active layer SACT1, the second sub-active layer SACT2, and the third sub-active layer SACT3 formed by the above-described deposition method may have different hydroxide (OH—) contents. A difference in the hydroxide (OH—) content between the sub-active layers SACT1 to SACT3 may be due to, for example, a difference in the flow rate of oxygen (O₂) gas introduced (or supplied) during the process of forming the sub-active material layers SAM1 to SAM3. As an example, the hydroxide (OH—) content in the sub-active layer may be inversely proportional to the flow rate of oxygen (O₂) gas introduced (or supplied) during the deposition process of the sub-active material layer. For example, as the flow rate of the oxygen (O₂) gas introduced (or supplied) during the deposition process of the first sub-active material layer SAM1 increases, the first sub-active layer SACT1 may contain a smaller amount of hydroxide (OH—). As still another example, the hydroxide (OH—) content of the sub-active layer may be inversely proportional to the power introduced (or supplied) during the deposition process of the sub-active material layer. For example, as the power introduced (or supplied) during the deposition process of the first sub-active material layer SAM1 increases, the first sub-active layer SACT1 may contain a smaller amount of hydroxide (OH—). For example, as described above, as the power increases, the density of the film (e.g., the sub-active material layer) increases, and thus the hydroxide (OH—) content in the film may decrease.

FIG. 10 is a schematic diagram for explaining a change in threshold voltage of a driving transistor according to a flow rate of oxygen (O₂) gas introduced (or supplied) during a deposition process.

An X-axis of FIG. 10 means a flow rate of oxygen (O₂) gas introduced (or supplied) during a deposition process, and a Y-axis of FIG. 10 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

As illustrated in FIG. 10, as the flow rate of the oxygen (O₂) gas introduced (or supplied) during the deposition process increases, the threshold voltage of the driving transistor may increase. For example, as the flow rate of the oxygen (O₂) gas increases, a dispersion of the threshold voltage of the driving transistor may show a decreasing trend.

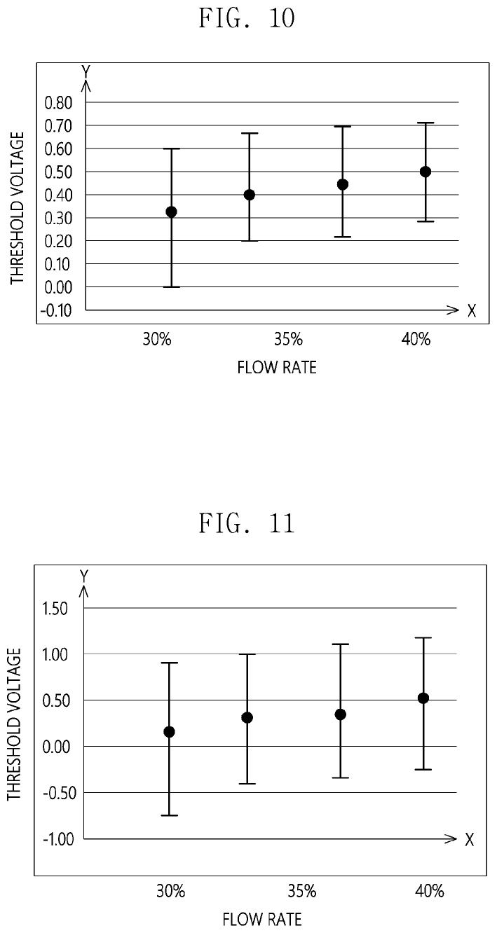

FIG. 11 is a schematic diagram for explaining a change in threshold voltage of a switching transistor according to a flow rate of oxygen gas (O₂) introduced (or supplied) during a deposition process.

An X-axis of FIG. 11 means a flow rate of oxygen (O₂) gas introduced (or supplied) during a deposition process, and a Y-axis of FIG. 11 means a threshold voltage of a switching transistor.

The switching transistor may be an n-type second transistor T2 or third transistor T3 including an active layer ACT (e.g., a metal oxide active layer or indium-gallium-zinc oxide active layer) formed by using, for example, the sputtering device of FIG. 8.

As illustrated in FIG. 11, as the flow rate of the oxygen (O₂) gas introduced (or supplied) during the deposition process increases, the threshold voltage of the switching transistor may increase. For example, as the flow rate of the oxygen (O₂) gas increases, a dispersion of the threshold voltage of the switching transistor may show a decreasing trend.

FIG. 12 is a schematic diagram for explaining a change amount (or variation) of a threshold voltage of a driving transistor according to a flow rate of oxygen gas (O₂) introduced (or supplied) during a deposition process.

An X-axis of FIG. 12 means a flow rate of oxygen (O₂) gas introduced (or supplied) during a deposition process, and a Y-axis of FIG. 12 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

The change amount (or variation) of the threshold voltage in FIG. 12 may refer to a difference voltage between a threshold voltage of the driving transistor under a first condition and a threshold voltage of the driving transistor under a second condition. For example, the threshold voltage of the driving transistor under the first condition may be, for example, a threshold voltage based on a current flowing through the driving transistor in case that a gate voltage applied to a gate electrode of the driving transistor is converted from a negative polarity to a positive polarity. For example, the threshold voltage of the driving transistor under the second condition may be, for example, a threshold voltage based on a current flowing through the driving transistor in case that a gate voltage applied to a gate electrode of the driving transistor is converted from a positive polarity to a negative polarity.

As illustrated in FIG. 12, as the flow rate of the oxygen (O₂) gas introduced (or supplied) during the deposition process increases, the change amount (or variation) of the threshold voltage of the driving transistor may show a generally increasing trend. For example, as illustrated in FIG. 12, as the flow rate of the oxygen (O₂) gas introduced (or supplied) during the deposition process increases, a dispersion of the change amount (or variation) of the threshold voltage of the driving transistor may show an increasing trend.

The difference (e.g., the change amount (or variation) of the threshold voltage) between the threshold voltage of the driving transistor under the first condition and the threshold voltage under the second condition may be related to the hysteresis characteristics of the driving transistor. The hysteresis characteristic may be related to a reliability of the driving transistor, and consequently, the change amount (or variation) of the threshold voltage of the driving transistor of FIG. 12 means the reliability of the driving transistor.

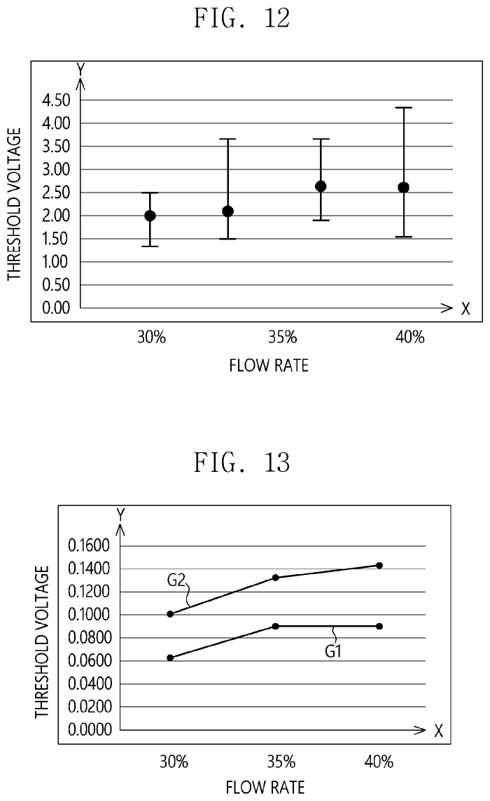

FIG. 13 is a schematic diagram for explaining a change amount (or variation) of a stress threshold voltage of a driving transistor according to a flow rate of oxygen gas (O₂) introduced (or supplied) during a deposition process.

An X-axis of FIG. 13 means a flow rate of oxygen (O₂) gas introduced (or supplied) during a deposition process, and a Y-axis of FIG. 13 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

The change amount (or variation) of the threshold voltage in FIG. 13 may refer to a difference between a threshold voltage of the driving transistor measured before a stress current is applied to the driving transistor and a threshold voltage of the driving transistor measured after the stress current is applied to the driving transistor.

A first curve G1 in FIG. 13 may refer to an average change amount (or variation) of threshold voltage, and a second curve G2 in FIG. 13 may refer to a change amount (or variation) of the threshold voltage of a worst case.

As illustrated in FIG. 13, as the flow rate of the oxygen (O₂) gas introduced (or supplied) during the deposition process increases, the change amount (or variation) of the stress threshold voltage of the driving transistor may show a generally increasing trend.

The change amount (or variation) of the threshold voltage according to the stress current described in FIG. 13 may be related to, for example, constant current stability characteristic of the driving transistor (or switching transistor). The constant current stability characteristic may be related to a reliability of the driving transistor, and consequently, the change amount (or variation) of the threshold voltage of the driving transistor of FIG. 13 means the reliability of the driving transistor.

FIG. 14 is a schematic diagram for explaining a change in threshold voltage of a driving transistor according to a power introduced (or supplied) during a deposition process.

An X-axis of FIG. 14 means a power introduced (or supplied) during a deposition process, and a Y-axis of FIG. 14 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

As illustrated in FIG. 14, as the power introduced (or supplied) during the deposition process increases, the threshold voltage of the driving transistor may show a decreasing trend. For example, as the power increases, a dispersion of the threshold voltage of the driving transistor may show a decreasing trend.

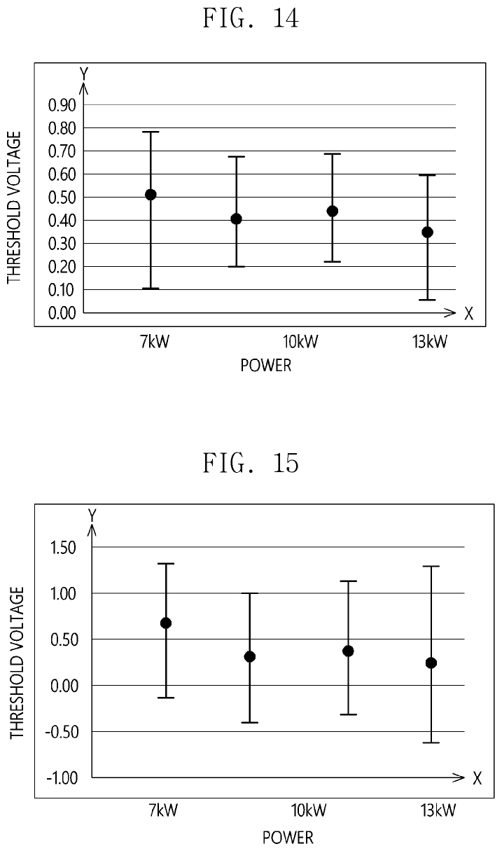

FIG. 15 is a schematic diagram for explaining a change in threshold voltage of a switching transistor according to a power introduced (or supplied) during a deposition process.

An X-axis of FIG. 15 means a power introduced (or supplied) during a deposition process, and a Y-axis of FIG. 15 means a threshold voltage of a switching transistor.

The switching transistor may be an n-type second transistor T2 or third transistor T3 including an active layer (e.g., a metal oxide active layer or indium-gallium-zinc oxide active layer) formed by using, for example, the sputtering device of FIG. 8.

As illustrated in FIG. 15, as the power introduced (or supplied) during the deposition process increases, the threshold voltage of the switching transistor may show a decreasing trend. For example, as the power increases, a dispersion of the threshold voltage of the switching transistor may show an increasing trend.

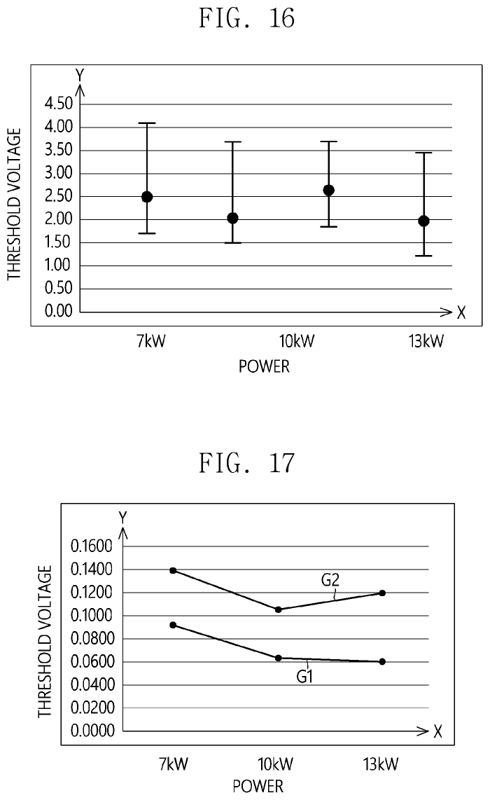

FIG. 16 is a schematic diagram for explaining a change amount (or variation) of a threshold voltage of a driving transistor according to a power introduced (or supplied) during a deposition process.

An X-axis of FIG. 16 means a flow rate of oxygen (O₂) gas introduced (or supplied) during a deposition process, and a Y-axis of FIG. 16 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

The change amount (or variation) of the threshold voltage in FIG. 16 may refer to a difference voltage between a threshold voltage of the driving transistor under a first condition and a threshold voltage of the driving transistor under a second condition. For example, the threshold voltage of the driving transistor under the first condition may be, for example, a threshold voltage based on a current flowing through the driving transistor in case that a gate voltage applied to a gate electrode of the driving transistor is converted from a negative polarity to a positive polarity. For example, the threshold voltage of the driving transistor under the second condition may be, for example, a threshold voltage based on a current flowing through the driving transistor in case that a gate voltage applied to a gate electrode of the driving transistor is converted from a positive polarity to a negative polarity.

As illustrated in FIG. 16, as the power introduced (or supplied) during the deposition process increases, the change amount (or variation) of the threshold voltage of the driving transistor may show a generally increasing trend. For example, as illustrated in FIG. 16, as the power introduced (or supplied) during the deposition process increases, a dispersion of the change amount (or variation) of the threshold voltage of the driving transistor may show a decreasing trend.

The difference (e.g., the change amount (or variation) of the threshold voltage) between the threshold voltage of the driving transistor under the first condition and the threshold voltage under the second condition may be related to the hysteresis characteristic of the driving transistor. The hysteresis characteristic may be related to a reliability of the driving transistor, and consequently, the change amount (or variation) of the threshold voltage of the driving transistor of FIG. 16 means the reliability of the driving transistor.

FIG. 17 is a schematic diagram for explaining a change amount (or variation) of a stress threshold voltage of a driving transistor according to a power introduced (or supplied) during a deposition process.

An X-axis of FIG. 17 means a power introduced (or supplied) during a deposition process, and a Y-axis of FIG. 17 means a threshold voltage of a driving transistor.

The driving transistor may be an n-type first transistor T1 including an active layer ACT (e.g., a metal oxide active layer or indium-gallium-zinc oxide active layer) formed by using, for example, the sputtering device of FIG. 8.

The change amount (or variation) of the threshold voltage in FIG. 17 may refer to a difference between a threshold voltage of the driving transistor measured before a stress current is applied to the driving transistor and a threshold voltage of the driving transistor measured after the stress current is applied to the driving transistor.

A first curve G1 in FIG. 17 may refer to an average change amount (or variation) of threshold voltage, and a second curve G2 in FIG. 17 may refer to a change amount (or variation) of the threshold voltage of a worst case.

As illustrated in FIG. 17, as the flow rate of the oxygen (O₂) gas introduced (or supplied) during the deposition process increases, the change amount (or variation) of the stress threshold voltage of the driving transistor may show a generally decreasing trend.

The change amount (or variation) of the threshold voltage according to the stress current described in FIG. 17 may be related to, for example, constant current stability characteristics of the driving transistor (or switching transistor). The constant current stability characteristic may be related to a reliability of the driving transistor, and consequently, the change amount (or variation) of the threshold voltage of the driving transistor of FIG. 17 means the reliability of the driving transistor.

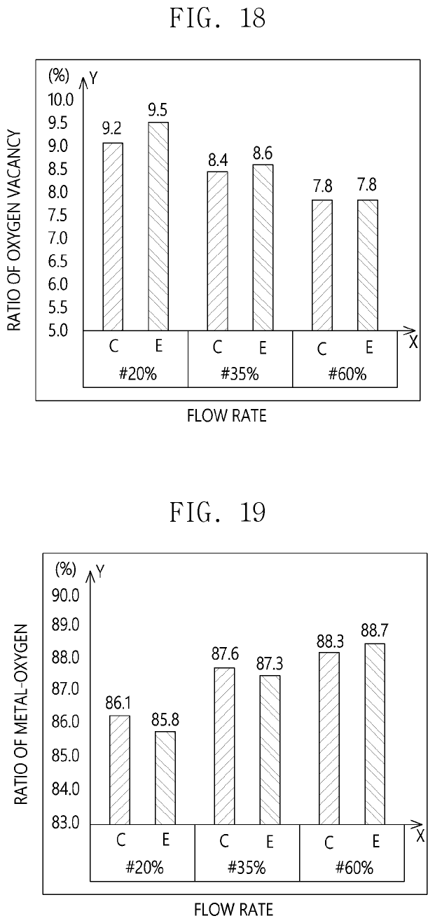

FIG. 18 is a schematic diagram for explaining a ratio occupied by oxygen vacancy (e.g., oxygen vacancy in a catalyst) among components of an active layer ACT of a display device according to an embodiment.

In FIG. 18, an X axis means a flow rate of oxygen (O₂) gas introduced (or supplied) during a deposition process of a sub-active material layer, and a Y-axis means a ratio of oxygen vacancy in the active layer ACT fabricated by the above-described deposition process. For example, in FIG. 18, “C” means a center portion of a substrate including unit display panels, and “E” means an edge portion of the substrate. Each unit display panel may include the above-described active layer.

As illustrated in FIG. 18, as the flow rate of oxygen (O₂) gas introduced (or supplied) during the deposition process of the sub-active material layer increases, the active layer ACT at the center portion and edge portion of the substrate may include a smaller amount of oxygen vacancies. Electron mobility may be improved as the amount of oxygen vacancies increases. For example, the second sub-active layer SACT2 may have a smaller amount of oxygen vacancies than the first sub-active layer SACT1 and/or the third sub-active layer SACT3.

FIG. 19 is a schematic diagram for explaining a ratio of a metal-oxygen bonding component (hereinafter, a metal-oxygen component) among components of an active layer ACT of a display device according to an embodiment.

In FIG. 19, an X axis means a flow rate of oxygen (O₂) gas introduced (or supplied) during a deposition process of a sub-active material layer, and a Y-axis means a ratio of a metal-oxygen component of the active layer ACT fabricated by the above-described deposition process. For example, in FIG. 19, “C” means a center portion of a substrate (e.g., mother substrate) including unit display panels, and “E” means an edge portion of the substrate. Each unit display panel may include the above-described active layer ACT.

For example, the metal component means a metal component in the active layer ACT including, for example, an indium-gallium-zinc-oxide (IGZO) oxide. For example, the metal may include at least one of indium, gallium, and zinc.

As illustrated in FIG. 19, as the flow rate of oxygen (O₂) gas introduced (or supplied) during the deposition process of the sub-active material layer increases, the active layer ACT at the center portion and edge portion of the substrate may include a larger amount of metal-oxygen components. For example, the second sub-active layer SACT2 may have a larger amount of metal-oxygen bonding component than the first sub-active layer SACT1 and/or the third sub-active layer SACT3.

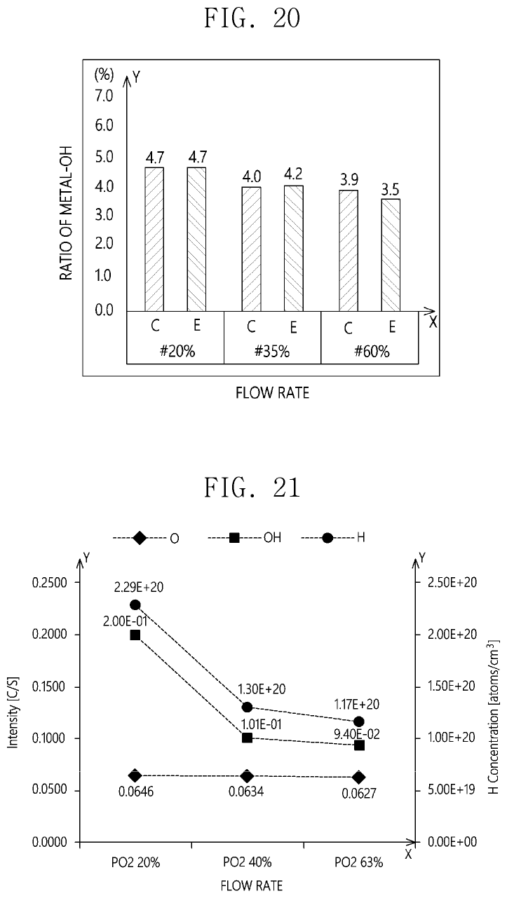

FIG. 20 is a schematic diagram for explaining ratios of metal and hydroxide (OH—) components among components of an active layer ACT of a display device according to an embodiment.

In FIG. 20, an X axis means a flow rate of oxygen (O₂) gas introduced (or supplied) during a deposition process of a sub-active material layer, and a Y-axis means a ratio of a metal-OH bonding component (hereinafter, a metal-OH component) of the active layer ACT fabricated by the above-described deposition process. For example, in FIG. 20, “C” means a center portion of a substrate (e.g., mother substrate) including unit display panels, and “E” means an edge portion of the substrate. Each unit display panel may include the above-described active layer.

For example, the metal component means a metal component in the active layer ACT including, for example, an indium-gallium-zinc-oxide (IGZO) oxide. For example, the metal may include at least one of indium, gallium, and zinc.

As illustrated in FIG. 20, as the flow rate of oxygen (O₂) gas introduced (or supplied) during the deposition process of the sub-active material layer increases, the active layer ACT at the center portion and edge portion of the substrate may include a smaller amount of metal-OH components. For example, the second sub-active layer SACT2 may have a smaller amount of metal-OH bonding component than the first sub-active layer SACT1 and/or the third sub-active layer SACT3.

FIG. 21 is a schematic diagram for explaining intensities of main components of an active layer ACT of a display device according to an embodiment.

In FIG. 21, an X-axis means a flow rate of oxygen (O₂) gas introduced (or supplied) during a deposition process of a sub-active material layer, a Y-axis on the left means an intensity of a corresponding component of the active layer ACT fabricated by the above-described deposition process, and a Y-axis on the right side means an atomic number density (e.g., hydrogen concentration) of hydrogen (H) in the active layer ACT fabricated by the above-described deposition process.

As illustrated in FIG. 21, as the flow rate of oxygen (O₂) gas introduced (or supplied) during the deposition process of the sub-active material layer increases, the intensity of an oxygen (O) component of the active layer ACT may decrease, the intensity of an hydroxide (OH—) component of the active layer ACT may decrease, and the intensity of a hydrogen (H) component of the active layer ACT may decrease.

For example, as shown from FIGS. 12 and 13, in order to improve the reliability of the driving transistor, the flow rate of oxygen (O₂) gas may be reduced during the deposition process. However, as illustrated in FIG. 10 described above, as the flow rate of oxygen (O₂) gas during the deposition process decreases, the threshold voltage of the driving transistor may also tend to decrease. Therefore, in case that the flow rate of oxygen (O₂) gas is increased to improve reliability, the driving transistor may be turned on even by a gate voltage smaller than a preset voltage level. For example, as illustrated in FIG. 12, as the flow rate of the oxygen (O₂) gas decreases, a dispersion of the threshold voltage of the driving transistor shows an increasing trend.

According to an embodiment, in case that the sub-active material layers are deposited in the same chamber 1000, since the magnitude of power and the flow rate of oxygen gas in each deposition area may be individually or independently controlled for each deposition area, appropriate power may be applied according to characteristics of the driving transistor for each deposition process, and the oxygen gas may be supplied at an appropriate flow rate. Therefore, the driving transistor (or switching transistor) fabricated according to the fabricating method of an embodiment may have an optimal threshold voltage capable of maintaining the reliability. For example, according to an embodiment, reliability of a transistor element may be improved in a state in which a threshold voltage of the transistor (e.g., n-type oxide transistor) is not shifted in a negative direction. For example, in order to prevent the above-described threshold voltage of the transistor from shifting in the negative direction, the flow rate of oxygen (O₂) gas during the formation (or deposition) process of the second sub-active layer SACT2 may increase as the power decreases. For example, in order to improve the reliability of the above-described transistor, the flow rate of oxygen (O₂) gas during the formation (or deposition) process of the first and third sub-active layers SACT1 and SACT3 may decrease as power increases. For example, in order to prevent the above-described threshold voltage of the transistor from shifting in the negative direction, the flow rate ratio of the oxygen (O₂) gas during the formation process of the second sub-active layer SACT2 may be higher than the flow rate of oxygen (O₂) gas during the formation process of the first sub-active layer SACT1 and/or the third sub-active layer SACT3, and the power during the formation process of the second sub-active layer SACT2 may be lower than the power during the formation process of the first sub-active layer SACT1 and/or the third sub-active layer SACT3. For example, in order to improve the reliability of the above-described transistor, the flow rate ratio of the oxygen (O₂) gas during the formation process of the first sub-active layer SACT1 and/or the third sub-active layer SACT3 may be lower than the flow rate of oxygen (O₂) gas during the formation process of the second sub-active layer SACT2, and the power during the formation process of the first sub-active layer SACT1 and/or the third sub-active layer SACT3 may be higher than the power during the formation process of the second sub-active layer SACT2.

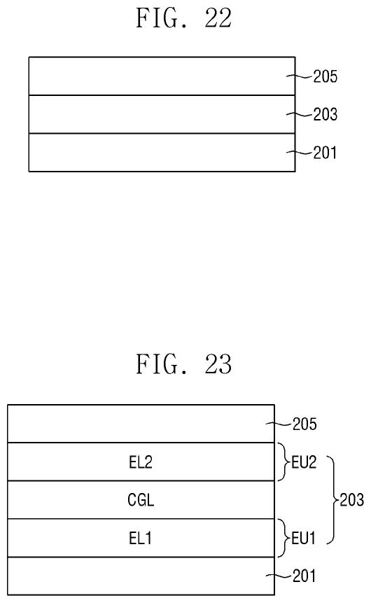

For example, the light emitting element LEL of FIG. 6 may have a tandem structure, which will be described with reference to FIGS. 22 to 29 as follows.

FIG. 22 is a schematic cross-sectional view illustrating a structure of a display element according to an embodiment, and FIGS. 23 to 26 are schematic cross-sectional views illustrating a structure of a light emitting element according to an embodiment.

Referring to FIG. 22, a light emitting element (e.g., an organic light emitting diode) according to an embodiment may include a pixel electrode 201, a common electrode 205, and an intermediate layer 203 between the pixel electrode 201 and the common electrode 205 described above.

The pixel electrode 201 may include light transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 201 may have a three-layer structure of ITO/Ag/ITO.

The common electrode 205 may be disposed on the intermediate layer 203. The common electrode 205 may include a low work function metal, alloy, electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The intermediate layer 203 may include a high molecule or low molecule organic material that emits light of a predetermined color. The intermediate layer 203 may further include a metal-containing compound such as an organometallic compound, an inorganic material such as a quantum dot, and the like, in addition to various organic materials.

In an embodiment, the intermediate layer 203 may include a single light emitting layer and a first functional layer and a second functional layer respectively disposed below and above the single light emitting layer. The first functional layer may include, for example, a hole transport layer HTL or a hole transport layer and a hole injection layer HIL. The second functional layer may be a component disposed on the light emitting layer and may be optional. For example, the intermediate layer 203 may or may not include the second functional layer. The second functional layer may include an electron transport layer ETL and/or an electron injection layer EIL.

In an embodiment, the intermediate layer 203 may include two or more emitting units sequentially stacked with each other between the pixel electrode 201 and the common electrode 205, and a charge generation layer CGL disposed between the two light emitting units. In case that the intermediate layer 203 includes the light emitting units and the charge generating layer, the light emitting element (e.g., organic light emitting diode) may be a tandem light emitting element. The light emitting element (e.g., the organic light emitting diode) may improve color purity and light emitting efficiency by having a stacked structure of light emitting units.

A light emitting unit may include a light emitting layer and a first functional layer and a second functional layer respectively disposed below and above the light emitting layer. The charge generation layer CGL may include a negative charge generation layer and a positive charge generation layer. Light emitting efficiency of the organic light emitting diode, which is the tandem light emitting element having the light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In an embodiment, as illustrated in FIG. 23, the light emitting element (e.g., the organic light emitting diode) may include a first light emitting unit EU1 including a first light emitting layer EL1 and a second light emitting unit EU2 including a second light emitting layer EL2 stacked in order. A charge generation layer CGL may be disposed between the first light emitting unit EU1 and the second light emitting unit EU2. For example, the light emitting element (e.g., the organic light emitting diode) may include the pixel electrode 201, the first light emitting layer EL1, the charge generation layer CGL, the second light emitting layer EL2, and the common electrode 205 stacked in order. The first functional layer and the second functional layer may be disposed below and above the first light emitting layer EL1, respectively. The first functional layer and the second functional layer may be included below and above the second light emitting layer EL2, respectively. The first light emitting layer EL1 may be a blue light emitting layer, and the second light emitting layer EL2 may be a yellow light emitting layer.

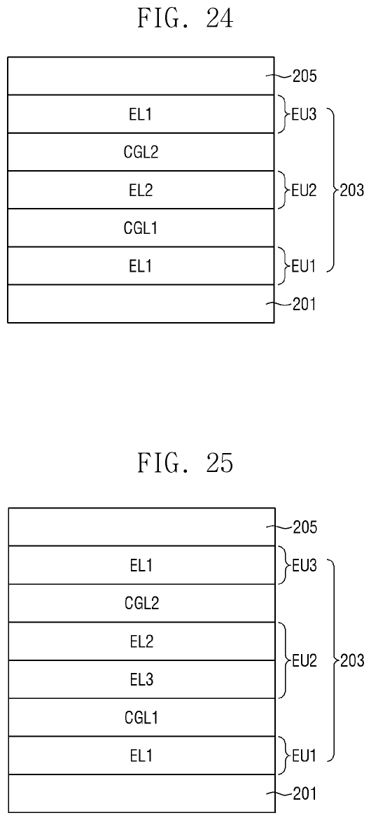

In an embodiment, as illustrated in FIG. 24, the light emitting element (e.g., the organic light emitting diode) may include a first light emitting unit EU1 and a third light emitting unit EU3 including a first light emitting layer EL1 and a second light emitting unit EU2 including a second light emitting layer EL2. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. For example, the light emitting element (e.g., the organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 stacked in order. The first functional layer and the second functional layer may be disposed below and above the first light emitting layer EL1, respectively. The first functional layer and the second functional layer may be disposed below and above the second light emitting layer EL2, respectively. The first light emitting layer EL1 may be a blue light emitting layer, and the second light emitting layer EL2 may be a yellow light emitting layer.

In an embodiment, in the light emitting element (e.g., the organic light emitting diode), the second light emitting unit EU2 may further include a third light emitting layer EL3 and/or a fourth light emitting layer ELA in contact with (e.g., in direct contact with) below and/or above the second light emitting layer EL2 in addition to the second light emitting layer EL2. For example, the direct contact means that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

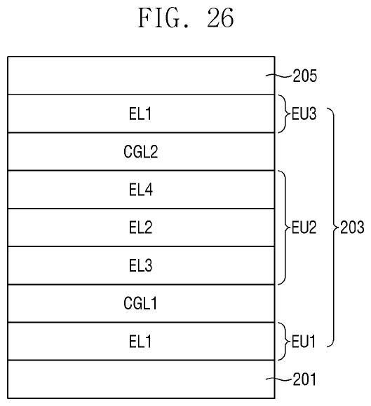

For example, as illustrated in FIG. 25, the light emitting element (e.g., the organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 stacked in order. In another example, as illustrated in FIG. 26, the light emitting element (e.g., the organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 stacked in order.

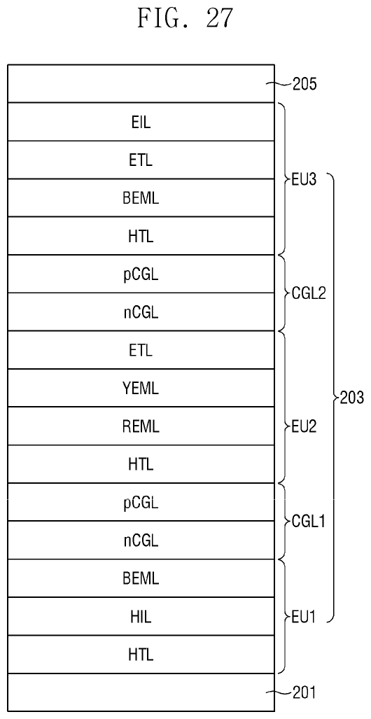

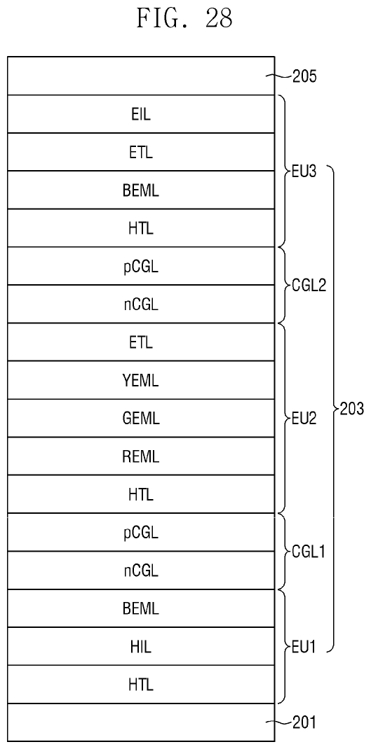

FIG. 27 is a schematic cross-sectional view illustrating an example of the organic light emitting diode of FIG. 25, and FIG. 28 is a schematic cross-sectional view illustrating an example of the organic light emitting diode of FIG. 26.

Referring to FIG. 27, the light emitting element (e.g., the organic light emitting diode) may include the first light emitting unit EU1, the second light emitting unit EU2, and the third light emitting unit EU3 sequentially stacked with each other. The first charge generation layer CGL1 may be disposed between the first light emitting unit EU1 and the second light emitting unit EU2, and the second charge generation layer CGL2 may be disposed between the second light emitting unit EU2 and the third light emitting unit EU3. The first charge generation layer CGL1 and the second charge generation layer CGL2 may include a negative charge generation layer nCGL and a positive charge generation layer pCGL, respectively.

The first light emitting unit EU1 may include a blue light emitting layer BEML. The first light emitting unit EU1 may further include a hole injection layer HIL and a hole transport layer HTL between the pixel electrode 201 and the blue light emitting layer BEML. In an embodiment, a p-doping layer may be further included between the hole injection layer HIL and the hole transport layer HTL. The P-doping layer may be formed by doping the hole injection layer (HIL) with a p-type doping material. In an embodiment, at least one of a blue light auxiliary layer, an electron blocking layer, and a buffer layer may be further included between the blue light emitting layer BEML and the hole transport layer HTL. The blue light auxiliary layer may increase light emission efficiency of the blue light emitting layer BEML. The blue light auxiliary layer may increase the light emission efficiency of the blue light emitting layer BEML by adjusting hole charge balance. The electron blocking layer may prevent injection of electrons into the hole transport layer HTL. The buffer layer may compensate for a resonance distance according to a wavelength of light emitted from the light emitting layer.

The second light emitting unit EU2 may include a yellow light emitting layer YEML and a red light emitting layer REML, which is in contact with (e.g., in direct contact with) the yellow light emitting layer YEML and disposed below the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the yellow light emitting layer YEML and the negative charge generation layer nCGL of the second charge generation layer CGL2.

The third light emitting unit EU3 may include a blue light emitting layer BEML. The third light emitting unit EU3 may further include a hole transport layer HTL between the positive charge generation layer pCGL of the second charge generation layer CGL2 and the blue light emitting layer BEML. The third light emitting unit EU3 may further include an electron transport layer ETL and an electron injection layer EIL between the blue light emitting layer BEML and the common electrode 205. The electron transport layer ETL may be formed as a single layer or multiple layers. In an embodiment, at least one of a blue light auxiliary layer, an electron blocking layer, and a buffer layer may be further included between the blue light emitting layer BEML and the hole transport layer HTL. At least one of the hole blocking layer and the buffer layer may be further included between the blue light emitting layer BEML and the electron transport layer ETL. The hole blocking layer may prevent hole injection into the electron transport layer ETL.

The light emitting element (e.g., the organic light emitting diode) illustrated in FIG. 28 is different from the light emitting element (e.g., the organic light emitting diode) illustrated in FIG. 26 in the stacked structure of the second light emitting unit EU2, and other compositions are the same. Referring to FIG. 30, the second light emitting unit EU2 may include a yellow light emitting layer YEML, a red light emitting layer REML, which is in contact with (e.g., in direct contact with) the yellow light emitting layer YEML and disposed below the yellow light emitting layer YEML, and a green light emitting layer GEML, which is in contact with (e.g., in direct contact with) the yellow light emitting layer YEML and disposed above the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the green light emitting layer GEML and the negative charge generation layer nCGL of the second charge generation layer CGL2.

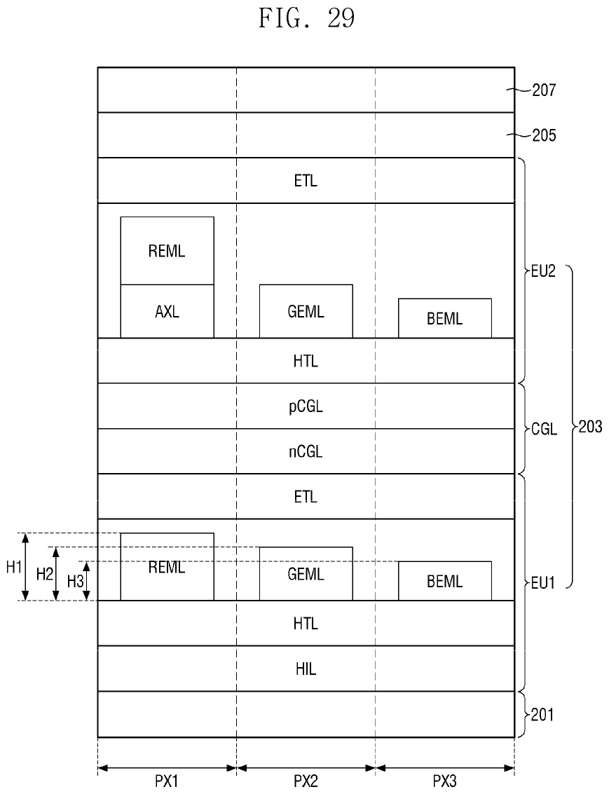

FIG. 29 is a schematic cross-sectional view illustrating a structure of a pixel of a display device according to an embodiment.

Referring to FIG. 29, a display panel 100 of a display device 10 may include pixels (e.g., the sub-pixels described above). The pixels may include a first pixel PX1, a second pixel PX2, and a third pixel PX3. Each of the first pixel PX1, the second pixel PX2, and the third pixel PX3 may include a pixel electrode 201, a common electrode 205, and an intermediate layer 203. In an embodiment, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include a first light emitting unit EU1 and a second light emitting unit EU2 sequentially stacked with each other, and a charge generation layer CGL between the first light emitting unit EU1 and the second light emitting unit EU2. The charge generation layer CGL may include a negative charge generation layer nCGL and a positive charge generation layer pCGL. The charge generation layer CGL may be a common layer continuously formed in the first pixel PX1, the second pixel PX2, and the third pixel PX3.

The first light emitting unit EU1 of the first pixel PX1 may include a hole injection layer HIL, a hole transport layer HTL, a red light emitting layer REML, and an electron transport layer ETL sequentially stacked with each other on the pixel electrode 201. The first light emitting unit EU1 of the second pixel PX2 may include a hole injection layer HIL, a hole transport layer HTL, a green light emitting layer GEML, and an electron transport layer ETL sequentially stacked with each other on the pixel electrode 201. The first light emitting unit EU1 of the third pixel PX3 may include a hole injection layer HIL, a hole transport layer HTL, a blue light emitting layer BEML, and an electron transport layer ETL sequentially stacked with each other on the pixel electrode 201. Each of the hole injection layer HIL, the hole transport layer HTL, and the electron transport layer ETL of the first light emitting unit EU1 may be a common layer continuously formed in the first pixel PX1, the second pixel PX2, and the third pixel PX3.

The second light emitting unit EU2 of the first pixel PX1 may include a hole transport layer HTL, an auxiliary layer AXL, a red light emitting layer REML, and an electron transport layer ETL sequentially stacked with each other on the charge generation layer CGL. The second light emitting unit EU2 of the second pixel PX2 may include a hole transport layer HTL, a green light emitting layer GEML, and an electron transport layer ETL sequentially stacked with each other on the charge generation layer CGL. The second light emitting unit EU2 of the third pixel PX3 may include a hole transport layer HTL, a blue light emitting layer BEML, and an electron transport layer ETL sequentially stacked with each other on the charge generation layer CGL. Each of the hole transport layer HTL and the electron transport layer ETL of the second light emitting unit EU2 may be a common layer continuously formed (or extended) in the first pixel PX1, the second pixel PX2, and the third pixel PX3. In an embodiment, at least one of a hole blocking layer and a buffer layer may be further included between the light emitting layer and the electron transport layer ETL in the second light emitting unit EU2 of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance and may include a resonance auxiliary material. For example, the auxiliary layer AXL and the hole transport layer HTL may include the same material.

In FIG. 29, the auxiliary layer AXL may be disposed only in the first pixel PX1, but embodiments are not limited thereto. For example, the auxiliary layer AXL may be disposed in at least one of the first pixel PX1, the second pixel PX2, and the third pixel PX3 to adjust the resonance distance of each of the first pixel PX1, the second pixel PX2, and the third pixel PX3.

The display panel 100 of the display device 10 may further include a capping layer 207 disposed outside the common electrode 205. The capping layer 207 may function to improve light emitting efficiency by a principle of constructive interference. Accordingly, light extraction efficiency of the light emitting element (e.g., the organic light emitting diode) may be increased, and thus, the light emitting efficiency of the light emitting element (e.g., the organic light emitting diode) may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method for fabricating a display device, the method comprising:
providing a substrate into a chamber;
forming an active material layer on the substrate by a plurality of deposition processes in the chamber;
forming an active layer by patterning the active material layer:
forming a transistor including a gate electrode overlapping the active layer; and
forming a pixel electrode on the transistor,
wherein at least two deposition processes among the plurality of deposition processes are performed by applying different magnitudes of power, respectively.

2. The method of claim 1, wherein the at least two deposition processes are performed by applying different flow rates of oxygen gas, respectively.

3. The method of claim 1, wherein the active layer includes:
a first sub-active layer disposed in a first sub-active area adjacent to the substrate;
a second sub-active layer disposed in a second sub-active area on the first sub-active area; and
a third sub-active layer disposed in a third sub-active area on the second sub-active area.

4. The method of claim 3, wherein the first sub-active layer, the second sub-active layer, and the third sub-active layer are integral with each other without an interface therebetween.

5. The method of claim 3, wherein
a first interface is formed between the first sub-active layer and the second sub-active layer, and
a second interface is formed between the second sub-active layer and the third sub-active layer.

6. The method of claim 3, further comprising:
forming a buffer film between the substrate and the active layer; and
forming a gate insulating film between the gate electrode and the active layer, wherein
the first sub-active area is disposed adjacent to the buffer film,
the third sub-active area is disposed adjacent to the gate insulating film, and
the second sub-active area is disposed between the first sub-active area and the third sub-active area.

7. The method of claim 6, wherein
the first sub-active layer in the first sub-active area is in contact with the buffer film, and
the third sub-active layer in the third sub-active area is in contact with the gate insulating film.

8. The method of claim 3, wherein the chamber includes:
a first deposition area for depositing a first sub-active material layer in the first sub-active area on the substrate;
a second deposition area for depositing a second sub-active material layer in the second sub-active area on the substrate; and
a third deposition area for depositing a third sub-active material layer in the third sub-active area on the substrate.

9. The method of claim 8, further comprising:
providing the substrate to the first deposition area;
providing the substrate to the second deposition area; and
providing the substrate to the third deposition area.

10. The method of claim 8, wherein
the plurality of deposition processes include:
forming the first sub-active material layer in the first sub-active area on the substrate by applying a first power to the first deposition area;
forming a second sub-active material layer in the second sub-active area on the substrate by applying a second power to the second deposition area; and
forming the third sub-active material layer in the third sub-active area on the substrate by applying a third power to the third deposition area, and
at least two of the first, second, and third powers have different magnitudes.

11. The method of claim 10, wherein
the first power has a magnitude different from a magnitude of the second power, and
the third power has a magnitude different from the magnitude of the second power.

12. The method of claim 10, wherein the first sub-active material layer, the second sub-active material layer, and the third sub-active material layer are integral with each other without an interface.

13. The method of claim 10, wherein
a first interface is formed between the first sub-active material layer and the second sub-active material layer, and
a second interface is formed between the second sub-active material layer and the third sub-active material layer.

14. The method of claim 10, wherein
the forming of the first sub-active material layer is performed by applying oxygen gas of a first flow rate to the first deposition area,
the forming of the second sub-active material layer is performed by applying oxygen gas of a second flow rate to the second deposition area,
the forming of the third sub-active material layer is performed by applying oxygen gas of a third flow rate to the third deposition area, and
at least two of the first, second, and third flow rates have different magnitudes.

15. The method of claim 14, wherein
the second flow rate is greater than the first flow rate and/or the third flow rate, and
the second power is smaller than the first power and/or the third power.

16. A display device comprising:
a substrate;
an active layer on the substrate;
a transistor including a gate electrode overlapping the active layer; and
a pixel electrode on the transistor, wherein
the active layer includes:
a first sub-active layer adjacent to the substrate,
a second sub-active layer disposed on the first sub-active layer, and
a third sub-active layer disposed on the second sub-active layer,
the second sub-active layer is disposed between the first sub-active layer and the third sub-active layer, and
the second sub-active layer has an amount of oxygen vacancies smaller than those of the first sub-active layer and/or the third sub-active layer.

17. The display device of claim 16, wherein the second sub-active layer includes an amount of hydrogen larger than those of the first sub-active layer and/or the third sub-active layer.

18. The display device of claim 16, wherein the second sub-active layer includes an amount of oxygen-metal bonding components larger than those of the first sub-active layer and/or the third sub-active layer.

19. The display device of claim 16, wherein the second sub-active layer includes an amount of metal-OH bonding components smaller than those of the first sub-active layer and/or the third sub-active layer.

20. The display device of claim 16, wherein the at least two of the first, second, and third sub-active layers have different densities.

21. The display device of claim 16, wherein the first sub-active layer, the second sub-active layer, and the third sub-active layer are integral with each other without an interface.

22. The display device of claim 16, wherein
a first interface is formed between the first sub-active layer and the second sub-active layer, and
a second interface is formed between the second sub-active layer and the third sub-active layer.
